(19) United States
(12) Patent Application Publication
(10) Pub. No.: US 2011/0091818 A1
(43) Pub. Date: Apr. 21, 2011

(54) PROCESS FOR PRODUCING PHOTORESIST PATTERN

(75) Inventors: Mitsuhiro HATA, Delmar, NY (US); Kazuhiko Hashimoto, Osaka (JP)

(73) Assignee: SUMITOMO CHEMICAL COMPANY, LIMITED, Tokyo (JP)

(21) Appl. No.: 12/906,522

(22) Filed: Oct. 18, 2010

(30) Foreign Application Priority Data
Oct. 21, 2009 (JP) 2009-242291

(51) Int. Cl. G03F 7/20

(52) U.S. Cl. 430/324

(57) ABSTRACT

The present invention provides a process for producing a photoresist pattern comprising the following steps (1) to (11):
(1) a step of applying the first photoresist composition comprising a resin comprising a structural unit having an acid-labile group in its side chain and being itself insoluble or poorly soluble in an alkali aqueous solution but becoming soluble in an alkali aqueous solution by the action of an acid, and an acid generator, on a substrate followed by conducting drying, thereby forming the first photoresist film,
(2) a step of prebaking the first photoresist film,
(3) a step of exposing the prebaked first photoresist film to radiation,
(4) a step of baking the exposed first photoresist film,
(5) a step of developing the baked first photoresist film with the first alkaline developer, thereby forming the first photoresist pattern,
(6) a step of forming a coating layer on the first photoresist pattern,
(7) a step of applying the second photoresist composition on the coating layer followed by conducting drying, thereby forming the second photoresist film,
(8) a step of prebaking the second photoresist film,
(9) a step of exposing the prebaked second photoresist film to radiation,
(10) a step of baking the exposed second photoresist film, and
(11) a step of developing the baked second photoresist film with the second alkaline developer, thereby forming the second photoresist pattern.

This nonprovisional application claims priority under 35 U.S.C. §119(a) on Patent Applications No. 2009-242291 filed in JAPAN on Oct. 21, 2009, the entire contents of which are hereby incorporated by reference.

### FIELD OF THE INVENTION

The present invention relates to a process for producing a photoresist pattern.

### BACKGROUND OF THE INVENTION

In recent years, a more miniaturized photoresist pattern has been demanded to produce in a process of production of a semiconductor using a lithography technology. As a process realizing to form a photoresist pattern having a line width of 32 nm or less, a double-patterning method has been proposed (e.g. Japanese Patent Laid-Open No. 2007-311508). The double-patterning method is a method in which a target photoresist pattern is formed by performing twice a pattern transfer step. According to the double-patterning method, a first photoresist pattern is formed at a pitch twice a target pitch via ordinary exposure and development, and thereafter, in a space between lines of the first photoresist pattern, a second photoresist pattern having the same pitch is formed by performing exposure and development again, and a target fine photoresist pattern is thereby formed.

### SUMMARY OF THE INVENTION

An object of the present invention is to provide a process for producing a photoresist pattern.

The present invention relates to the followings:

<1> A process for producing a photoresist pattern comprising the following steps (1) to (11):

(1) a step of applying the first photoresist composition comprising a resin comprising a structural unit having an acid-labile group in its side chain and being itself insoluble or poorly soluble in an alkali aqueous solution but becoming soluble in an alkali aqueous solution by the action of an acid, and an acid generator, on a substrate followed by conducting drying, thereby forming the first photoresist film,

(2) a step of prebaking the first photoresist film,

(3) a step of exposing the prebaked first photoresist film to radiation,

(4) a step of baking the exposed first photoresist film,

(5) a step of developing the baked first photoresist film with the first alkaline developer, thereby forming the first photoresist pattern,

(6) a step of forming a coating layer on the first photoresist pattern,

(7) a step of applying the second photoresist composition on the coating layer followed by conducting drying, thereby forming the second photoresist film,

(8) a step of prebaking the second photoresist film,

(9) a step of exposing the prebaked second photoresist film to radiation,

(10) a step of baking the exposed second photoresist film, and

(11) a step of developing the baked second photoresist film with the second alkaline developer, thereby forming the second photoresist pattern;

<2> The process according to <1>, wherein the step (6) comprises the following steps (6a) to (6c):

(6a) a step of applying a coating composition comprising a resin for forming a coating layer and a solvent for a coating layer on the first photoresist pattern,

(6b) a step of baking the formed coating composition layer on the first photoresist pattern to prepare a coating film, and

(6c) a step of developing the baked coating film with the developer, thereby forming the coating layer on the first photoresist pattern;

<3> The process according to <1> or <2>, wherein the resin for forming a coating layer is a resin comprising a structural unit represented by the formula (A1):

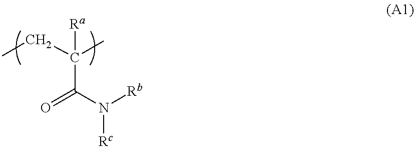

wherein R^{a} represents a hydrogen atom or a C1-C4 alkyl group, R^{b} and R^{c} each independently represent a hydrogen atom, a C1-C6 alkyl group or a C6-C10 aromatic hydrocarbon group, or R^{b} and R^{c} are bonded each other to form a C1-C6 alkylene group, and the alkyl group can have one or more hydroxyl group, the aromatic hydrocarbon group can have one or more C1-C4 perfluoroalkyl group, and one or more —CH₂— in the alkyl group and the alkylene group can be replaced by —O—, —CO— or —NR^{d}— in which R^{d} represents a hydrogen atom or a C1-C4 alkyl group, and —CH═CH— in the aromatic hydrocarbon group can be replaced by —CO—O—;
<4> The process according to <1> or <2>, wherein the resin for forming a coating layer is a resin comprising a structural unit represented by the formula (A2):

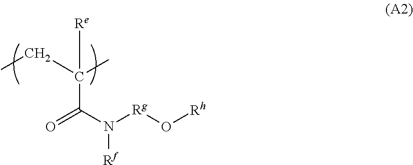

wherein R^{e}, R^{f} and R^{h} each independently represent a hydrogen atom or a C1-C4 alkyl group, R^{g} represents a C1-C4 alkylene group;
<5> The process according to any one of <1> to <4>, wherein the solvent for a coating layer is water.

### DESCRIPTION OF PREFERRED EMBODIMENTS

The first photoresist composition used in the present invention comprises the following two components;

Component (a): a resin comprising a structural unit having an acid-labile group in its side chain and being itself insoluble or poorly soluble in an alkali aqueous solution but becoming soluble in an alkali aqueous solution by the action of an acid, and Component (b): an acid generator.

First, Component (a) will be illustrated.

In this specification, “the resin is itself insoluble or poorly soluble in an alkali aqueous solution” means 100 mL or more of an alkali aqueous solution is needed to dissolve 1 g or 1 mL of the first photoresist composition containing the resin, and “the resin is soluble in an alkali aqueous solution” means less than 100 mL of an alkali aqueous solution is needed to dissolve 1 g or 1 mL of the first photoresist composition containing the resin.

In this specification, “an acid-labile group” means a group capable of being eliminated by the action of an acid.

In this specification, “—COOR” may be described as “a structure having ester of carboxylic acid”, and may also be abbreviated as “ester group”. Specifically, “—COOC(CH₃)₃” may be described as “a structure having tert-butyl ester of carboxylic acid”, or be abbreviated as “tert-butyl ester group”.

Examples of the acid-labile group include a structure having ester of carboxylic acid such as alkyl ester group in which a carbon atom adjacent to the oxygen atom is quaternary carbon atom, alicyclic ester group in which a carbon atom adjacent to the oxygen atom is quaternary carbon atom, and a lactone ester group in which a carbon atom adjacent to the oxygen atom is quaternary carbon atom. The “quaternary carbon atom” means a “carbon atom joined to four substituents other than hydrogen atom”. Other examples of the acid-labile group include a group having a quaternary carbon atom joined to three carbon atoms and an —OR′, wherein R′ represents an alkyl group.

Examples of the acid-labile group include an alkyl ester group in which a carbon atom adjacent to the oxygen atom is quaternary carbon atom such as a tert-butyl ester group; an acetal type ester group such as a methoxymethyl ester, ethoxymethyl ester, 1-ethoxyethyl ester, 1-isobutoxyethyl ester, 1-isopropoxyethyl ester, 1-ethoxypropoxy ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester and tetrahydro-2-pyranyl ester group; an alicyclic ester group in which a carbon atom adjacent to the oxygen atom is quaternary carbon atom, such as an isobornyl ester, 1-alkylcycloalkyl ester, 2-alkyl-2-adamantyl ester and 1-(1-adamantyl)-1-alkylalkyl ester group. The above-mentioned adamantyl group may have one or more hydroxyl groups.

As the acid-labile group, a group represented by the formula (1a):

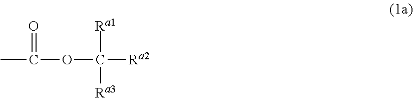

wherein R^{a1}, R^{a2} and R^{a3} independently each represent a C1-C8 alkyl group or a C5-C10 saturated cyclic hydrocarbon group, or R^{a1} and R^{a2} are bonded each other to form a C5-C10 ring, is preferable.

Examples of the C1-C8 alkyl group include a methyl group, an ethyl group, a propyl group, an isopropyl group, a butyl group, a pentyl group, a hexyl group, a heptyl group and an octyl group. The C5-C10 saturated cyclic hydrocarbon group may be monocyclic or polycyclic, and examples thereof include the followings.

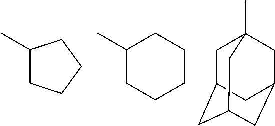

Examples of the group represented by the following:

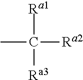

include the followings.

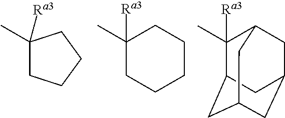

The group represented by the formula (1a) wherein R^{a1}, R^{a2} and R^{a3} independently each represent a C1-C8 alkyl group such as a tert-butoxycarbonyl group, the group represented by the formula (1a) wherein R^{a1} and R^{a2} are bonded each other to form a cyclohexane ring and R^{a3} is a C1-C8 alkyl group such as a 1-alkyl-1-cyclohexyloxycarbonyl group, the group represented by the formula (1a) wherein R^{a1} and R^{a2} are bonded each other to form an adamantane ring and R^{a3} is a C1-C8 alkyl group such as a 2-alkyl-2-adamantyloxycarbonyl group, and the group represented by the formula (Ia) wherein R^{ai} and R^{a2} are C1-C8 alkyl groups and R^{a3} is an adamantyl group such as a 1-(1-adamantyl)-1-alkylalkoxycarbonyl group are more preferable.

Examples of the structural unit having an acid-labile group in its side chain include a structure unit derived from an ester of acrylic acid, a structural unit derived from an ester of methacrylic acid, a structural unit derived from an ester of norbornenecarboxylic acid, a structural unit derived from an ester of tricyclodecenecarboxylic acid and a structural unit derived from an ester of tetracyclodecenecarboxylic acid. The structure units derived from the ester of acrylic acid and from the ester of methacrylic acid are preferable, and the structural unit derived from an acrylic acid ester or a methacrylic acid ester wherein a carbon atom adjacent to the oxygen atom in the ester part is a quaternary carbon atom and the acrylic acid ester and the methacrylic acid ester have 5 to 30 carbon atoms is more preferable.

The resin can be obtained by conducting polymerization reaction of a monomer or monomers having the acid-labile group and an olefinic double bond. The polymerization reaction is usually carried out in the presence of a radical initiator.

Among the monomers, those having a bulky and acid-labile group such as a saturated cyclic hydrocarbon ester group (e.g. a 1-alkyl-1-cyclohexyl ester group, a 2-alkyl-2-adamantyl ester group and 1-(1-adamantyl)-1-alkylalkyl ester group) are preferable, since excellent resolution is obtained when the resin obtained is used in the photoresist composition. Especially, monomers having a saturated cyclic hydrocarbon ester group containing a bridged structure such as a 2-alkyl-2-adamantyl ester group and 1-(1-adamantyl)-1-alkylalkyl ester group are more preferable.

Examples of such monomer containing the bulky and acid-labile group include a 1-alkyl-1-cyclohexyl acrylate, a 1-alkyl-1-cyclohexylmethacrylate, a 2-alkyl-2-adamantyl acrylate, a 2-alkyl-2-adamantyl methacrylate, 1-(1-adamantyl)-1-alkylalkyl acrylate, a 1-(1-adamantyl)-1-alkylalkyl methacrylate, a 2-alkyl-2-adamantyl 5-norbornene-2-carboxylate, a 1-(1-adamantyl)-1-alkylalkyl 5-norbornene-2-carboxylate, a 2-alkyl-2-adamantyl a-chloroacrylate and a 1-(1-adamantyl)-1-alkylalkyl a-chloroacrylate.

Among them, preferred are the 1-alkyl-1-cyclohexyl acrylate, the 1-alkyl-1-cyclohexyl methacrylate, the 2-alkyl-2-adamantyl acrylate and the 2-alkyl-2-adamantyl methacrylate. Typical examples thereof include 1-ethyl-1-cyclohexyl acrylate, 1-ethyl-1-cyclohexyl methacrylate, 2-methyl-2-adamantylacrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate, and 2-butyl-2-adamantyl acrylate, and 1-ethyl-1-cyclohexyl acrylate, 1-ethyl-1-cyclohexyl methacrylate, 2-ethyl-2-adamantyl acrylate, 2-ethyl-2-adamantyl methacrylate, 2-isopropyl-2-adamantyl acrylate and 2-isopropyl-2-adamantyl methacrylate are preferable. Two or more kinds of monomers having a group or groups dissociated by the action of the acid may be used together, if necessary.

The 2-alkyl-2-adamantyl acrylate can be usually produced by reacting a 2-alkyl-2-adamantanol or a metal salt thereof with an acrylic halide, and the 2-alkyl-2-adamantyl methacrylate can be usually produced by reacting a 2-alkyl-2-adamantanol or a metal salt thereof with a methacrylic halide.

The content of the structural unit having an acid-labile group in the resin is usually 10 to 80% by mole based on total molar of all the structural units of the resin. When the resin comprises the structural unit derived from the 2-alkyl-2-adamantyl acrylate or the 2-alkyl-2-adamantyl methacrylate, the content thereof is preferably 15% by mole or more based on total molar of all the structural units of the resin.

The resin can also contain one or more structural units having one or more highly polar substituents. Examples of the structural unit having one or more highly polar substituents include a structural unit having a hydrocarbon group having at least one selected from the group consisting of a hydroxyl group, a cyano group, a nitro group and an amino group and a structural unit having a hydrocarbon group having one or more —CO—O—, —CO—, —O—, —SO₂— or. A structural unit having a saturated cyclic hydrocarbon group having a cyano group or a hydroxyl group, a structural unit having a saturated cyclic hydrocarbon group in which one or more —CH₂— replaced by —O— or —CO—, and a structural unit having a lactone structure in its side chain are preferable. Examples thereof include a structural unit derived from 2-norbornene having one or more hydroxyl groups, a structural unit derived from acrylonitrile or methacrylonitrile, a structural unit derived from an alkyl acrylate or an alkyl methacrylate in which a carbon atom adjacent to oxygen atom is secondary or tertiary carbon atom, a structural unit derived from hydroxyl-containing adamantyl acrylate or hydroxyl-containing adamantyl methacrylate, a structural unit derived from styrene monomer such as p-hydroxystyrene and m-hydroxystyrene, and a structural unit derived from a structural unit derived from 1-adamantyl acrylate or 1-adamantyl methacrylate. Among them, preferred are a structural unit derived from hydroxyl-containing adamantyl acrylate or hydroxyl-containing adamantyl methacrylate, a structural unit derived from carbonyl-containing adamantyl acrylate or carbonyl-containing adamantyl methacrylate and a structural unit having a lactone structure in its side chain. Herein, the 1-adamantyloxycarbonyl group is the acid-stable group though the carbon atom adjacent to oxygen atom is the quaternary carbon atom.

Examples of the structural unit derived from hydroxyl-containing adamantyl acrylate or hydroxyl-containing adamantyl methacrylate include a structural unit derived from 3-hydroxy-1-adamantyl acrylate; a structural unit derived from 3-hydroxy-1-adamantyl methacrylate; a structural unit derived from 3,5-dihydroxy-1-adamantyl acrylate; and a structural unit derived from 3,5-dihydroxy-1-adamantyl methacrylate.

When the resin has a structural unit derived from hydroxyl-containing adamantyl acrylate or hydroxyl-containing adamantyl methacrylate, the content thereof is preferably 5 to 50% by mole based on 100% by mole of all the structural units of the resin.

3-Hydroxy-1-adamantyl acrylate, 3-hydroxy-1-adamantyl methacrylate, 3,5-dihydroxy-1-adamantyl acrylate and 3,5-dihydroxy-1-adamantyl methacrylate can be produced, for example, by reacting corresponding hydroxyadamantane with acrylic acid, methacrylic acid or its acid halide, and they are also commercially available.

Examples of the monomer giving the structural unit derived from carbonyl-containing adamantyl acrylate or carbonyl-containing adamantyl methacrylate include monomers represented by the formulae (a1) and (a2):

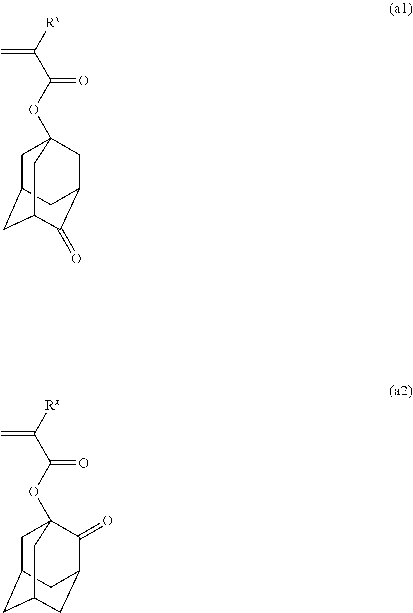

wherein R^{x} represents a hydrogen atom or a methyl group, and the monomer represented by the formula (a1) is preferable.

When the resin has a structural unit derived from the monomer represented by the formula (a1) or (a2), the content thereof is preferably 2 to 20% by mole based on 100% by mole of all the structural units of the resin.

Examples of the structural unit having a lactone structure in its side chain include a structural unit derived from α-acryloyloxy-γ-butyrolactone;

a structural unit derived from α-methacryloyloxy-γ-butyrolactone;
a structural unit derived from α-acryloyloxy-β,β-dimethyl-γ-butyrolactone;
a structural unit derived from α-methacryloyloxy-β,β-dimethyl-γ-butyrolactone;
a structural unit derived from α-acryloyloxy-α-methyl-γ-butyrolactone;
a structural unit derived from α-methacryloyloxy-α-methyl-γ-butyrolactone;
a structural unit derived from β-acryloyloxy-γ-butyrolactone;
a structural unit derived from β-methacryloyloxy-γ-butyrolactone;
a structural unit derived from β-methacryloyloxy-α-methyl-γ-butyrolactone;
a structural unit represented by the formula (a):

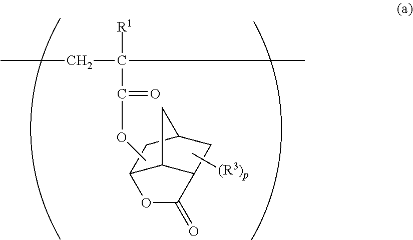

wherein R¹ represents a hydrogen atom or a methyl group, R³ represents a methyl group and p represents an integer of 0 to 3; and a structural unit represented by the formula (b):

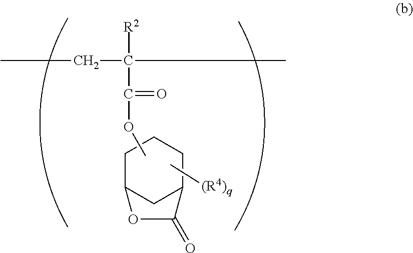

wherein R² represents a hydrogen atom or a methyl group, R⁴ represents a methyl group and q represents an integer of 0 to 3.

The acryloyloxy-γ-butyrolactone and the methacryloyloxy-γ-butyrolactone can be produced by reacting corresponding α- or β-bromo-γ-butyrolactone with acrylic acid or methacrylic acid, or reacting corresponding α- or β-hydroxy-γ-butyrolactone with the acrylic halide or the methacrylic halide.

When the resin has the structural unit having a lactone structure in its side chain, the content thereof is preferably 2 to 20% by mole based on 100% by mole of all the structural units of the resin.

Among them, preferred are the resin having at least one structural unit selected from the group consisting of the structural unit derived from 3-hydroxy-1-adamantyl acrylate, the structural unit derived from 3-hydroxy-1-adamantyl methacrylate, the structural unit derived from 3,5-dihydroxy-1-adamantyl acrylate, the structural unit derived from 3,5-dihydroxy-1-adamantyl methacrylate, the structural unit derived from α-acryloyloxy-γ-butyrolactone; the structural unit derived from α-methacryloyloxy-γ-butyrolactone; the structural unit derived from β-acryloyloxy-γ-butyrolactone and the structural unit derived from β-methacryloyloxy-γ-butyrolactone.

When the exposing is conducted using KrF excimer laser, the resin preferably has a structural unit derived from a styrene monomer such as p-hydroxystyrene and m-hydroxystyrene.

The resin usually has 5,000 or more of the weight-average molecular weight, preferably 6,500 or more of the weight-average molecular weight, more preferably 7, 000 or more of the weight-average molecular weight, and still more preferably 7,500 or more of the weight-average molecular weight. When the weight-average molecular weight of the resin is too large, defect of the photoresist film tends to generate, and therefore, the resin preferably has 40,000 or less of the weight-average molecular weight, more preferably 39,000 or less of the weight-average molecular weight, much more preferably 38,000 or less of the weight-average molecular weight, and especially preferably 37,000 or less of the weight-average molecular weight. The weight-average molecular weight can be measured with gel permeation chromatography.

Component (a) contains one or more resins.

In the first photoresist composition, the content of Component (a) is usually 70 to 99.9% by weight based on the amount of solid components and preferably 80 to 99.9% by weight. In this specification, “solid components” means sum of components other than a solvent(s) in the photoresist composition.

Next, Component (b) will be illustrated.

The acid generator is a substance which is decomposed to generate an acid by applying a radiation such as a light, an electron beam or the like on the substance itself or on a photoresist composition containing the substance. The acid generated from the acid generator acts on the resin resulting in cleavage of the acid-labile group existing in the resin, and the resin becomes soluble in an aqueous alkali solution.

The acid generator may be nonionic or ionic. Examples of the nonionic acid generator include organic halides, sulfonate esters such as 2-nitrobenzyl ester, aromatic sulfonate, oxime sulfonate, N-sulfonyloxyimide, sulfonyloxyketone and DNQ 4-sulfonate, and sulfones such as disulfone, ketosulfone and sulfonyldiazomethane. Examples of the ionic acid generator include onium salts such as a diazonium salt, a phosphonium salt, a sulfonium salt and an iodonium salt, and examples of the anion of the onium salt include sulfonic acid anion, sulfonylimide anion and sulfonylmethide anion.

A fluorine-containing acid generator is preferable, and a salt represented by the formula (I):

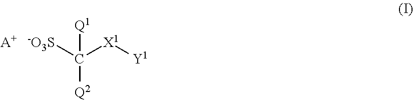

wherein Q¹ and Q² each independently represent a fluorine atom or a C1-C6 perfluoroalkyl group, X¹ represents a single bond or a C1-C17 divalent saturated hydrocarbon group which can have one or more substituents and in which one or more —CH₂— can be replaced by —O— or —CO—, Y¹ represents a C1-C36 aliphatic hydrocarbon group which can have one or more substituents, a C3-C36 saturated cyclic hydrocarbon group which can have one or more substituents, or a C6-C36 aromatic hydrocarbon group which can have one or more substituents, and one or more —CH₂— in the aliphatic hydrocarbon group and the saturated cyclic hydrocarbon group can be replaced by —O— or —CO—, and A⁺ represents an organic cation, is more preferable.

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. It is preferred that Q¹ and Q² each independently represent a fluorine atom or a trifluoromethyl group, and it is more preferred that Q¹ and Q² represent fluorine atoms.

Examples of the C1-C17 divalent saturated hydrocarbon group include a C1-C17 linear alkylene group such as a methylene group, an ethylene group, a propane-1,3-diyl group, a propane-1,2-diyl group, a butane-1,4-diyl group, a butane-1,3-diyl group, a pentane-1,5-diyl group, a hexane-1,6-diyl group, a heptane-1,7-diyl group, an octane-1,8-diyl group, a nonane-1,9-diyl group, a decane-1,10-diyl group, a undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group.

Examples of the C1-C17 saturated hydrocarbon group in which one or more methylene groups are replaced by —O— or —CO— include *—CO—O—, *—CO—O—X¹¹—, *—O—CO—X¹¹—, *—O—X¹²—, *—X¹¹—CO—O—, *—X¹¹—O—CO—, *—X¹³—O—X¹⁴—, *—CO—O—X¹⁵—CO—O—, and *—CO—O—X¹⁶—O— wherein X¹¹ represents a C1-C15 alkanediyl group, X¹² represents a C1-C16 alkanediyl group, X¹³ represents a C1-C15 alkanediyl group, X¹⁴ represents a C1-C15 alkanediyl group, with proviso that total carbon number of X¹³ and X¹⁴ is 1 to 15, X¹⁵ represents a C1-C13 alkanediyl group and X¹⁶ represents a C1-C14 alkanediyl group, and * represents a binding position to —C(Q¹)(Q²)-. Among them, preferred are *—CO—O—, *—CO—O—X¹¹—, *—X¹¹—O— and *—X¹¹—CO—O—, and more preferred are *—CO—O—, *—CO—O—X¹¹— and *—X¹¹—CO—O—, and much more preferred is *—CO—O— and *—CO—O—X¹¹—.

Examples of the C1-C36 aliphatic hydrocarbon group represented by Y¹ include a C1-C36 alkyl group such as a methyl group, an ethyl group, a propyl group, an isopropyl group, a butyl group, an isobutyl group, a sec-butyl group, a tert-butyl group, a pentyl group, a neopentyl group, a 1-methylbutyl group, a 2-methylbutyl group, a 1,2-dimethylpropyl group, a 1-ethylpropyl group, a hexyl group, a-1-methylpentyl group, a heptyl group, an octyl group, a 2-ethylhexyl group, a nonyl group, a decyl group, an undecyl group and a dodecyl group, and a C1-C6 alkyl group is preferable. Examples of the C3-C36 saturated cyclic hydrocarbon group represented by Y¹ include a cylopropyl group, a cyclobutyl group, a cyclopentyl group, a cyclohexyl group, a cycloheptyl group, a cyclooctyl group, a cyclononyl group, a cyclodecyl group, a norbornyl group, a 1-adamantyl group, a 2-adamantyl group, an isobornyl group, and the groups represented by the followings.

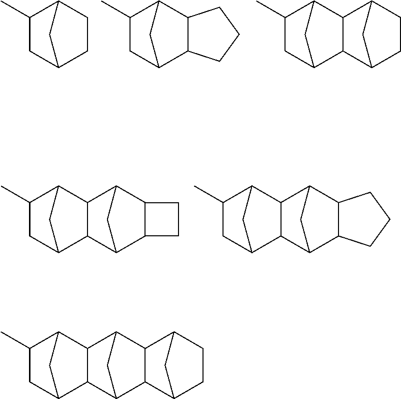

One or more —CH₂— in the saturated cyclic hydrocarbon group can be replaced by —O— or —CO—.

Examples of the aromatic hydrocarbon group include a phenyl group, a naphthyl group and an anthryl group.

Examples of the substituent of the aliphatic hydrocarbon group, saturated cyclic hydrocarbon group and the aromatic hydrocarbon group include a halogen atom, a hydroxyl group, a C1-C12 aliphatic hydrocarbon group, a C3-C12 saturated cyclic hydrocarbon group, a C6-C20 aromatic hydrocarbon group, a C1-C4 perfluoroalkyl group, a C1-C6 alkoxy group, a C1-C6 hydroxyalkyl group, a C7-C21 aralkyl group, a glycidyloxy group and a C2-C4 acyl group. Examples of the halogen atom include a fluorine atom, a chlorine atom, a bromine atom and an iodine atom. Examples of the aliphatic hydrocarbon group, the saturated cyclic hydrocarbon group and the C6-C20 aromatic hydrocarbon group include the same as described above. Examples of the C1-C6 hydroxyalkyl group include a hydroxymethyl group, a 2-hydroxyethyl group, a 3-hydroxypropyl group, a 4-hydroxybutyl group, a 5-hydroxypentyl group and a 6-hydroxyhexyl group. Examples of the alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group. Examples of the C7-C21 aralkyl group include a benzyl group, a phenethyl group, a phenylpropyl group, a trityl group, a naphthylmethyl group and a naphthylethyl group. Examples of the C2-C4 acyl group include an acetyl group, a propionyl group and a butyryl group.

As the acid generator, a salt represented by the formula (V) or (VI):

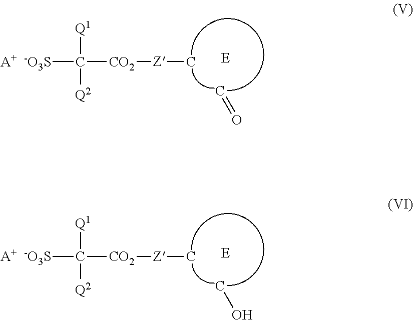

wherein ring E represents a C3-C30 cyclic hydrocarbon group having a carbonyl group or a hydroxyl group and the cyclic hydrocarbon group can have a C1-C6 alkyl group, a C1-C6 alkoxy group, a C1-C4 perfluoroalkyl group, a C1-C6 hydroxyalkyl group, a hydroxyl group or a cyano group, Z′ represents a single bond or a C1-C4 alkylene group, and Q¹, Q² and Ar⁺ are the same meanings as defined above, is preferable.

Examples of the C1-C4 alkylene group include a methylene group, a dimethylene group, a trimethylene group and a tetramethylene group, and a methylene group and a dimethylene group are preferable.

As the acid generator, a salt represented by the formula (III):

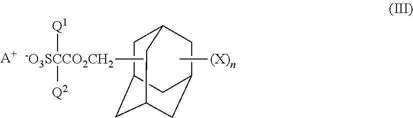

wherein Q¹, Q² and A⁺ are the same meanings as defined above, and X independently each represents a hydroxyl group or a C1-C6 hydroxyalkyl group, and n represents an integer of 1 to 9, is more preferable, and the salt represented by the formula (III) wherein n is 1 or 2 is especially preferable.

Examples of the anions of the salts represented by the formula (I) include the followings.

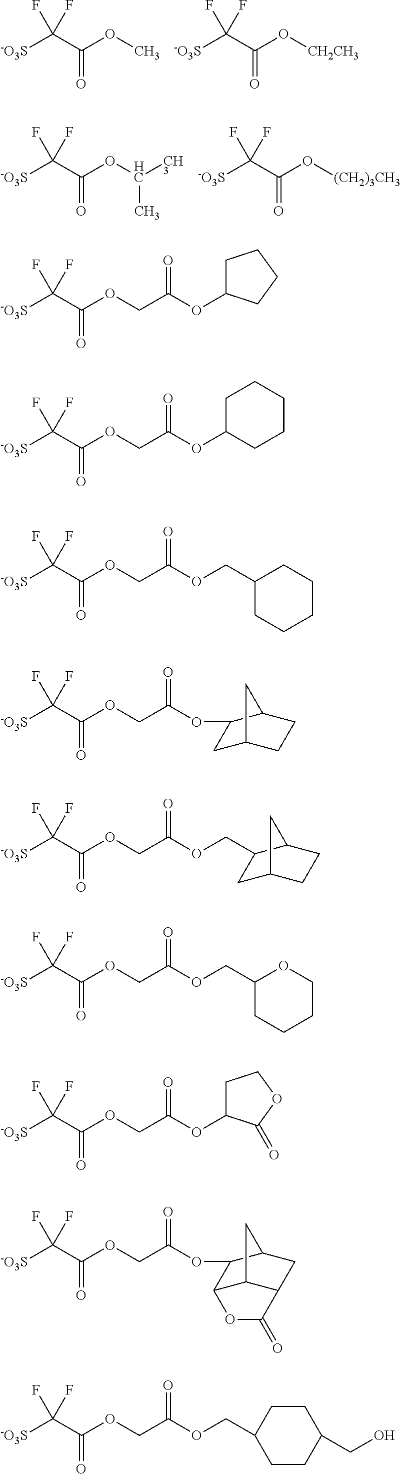

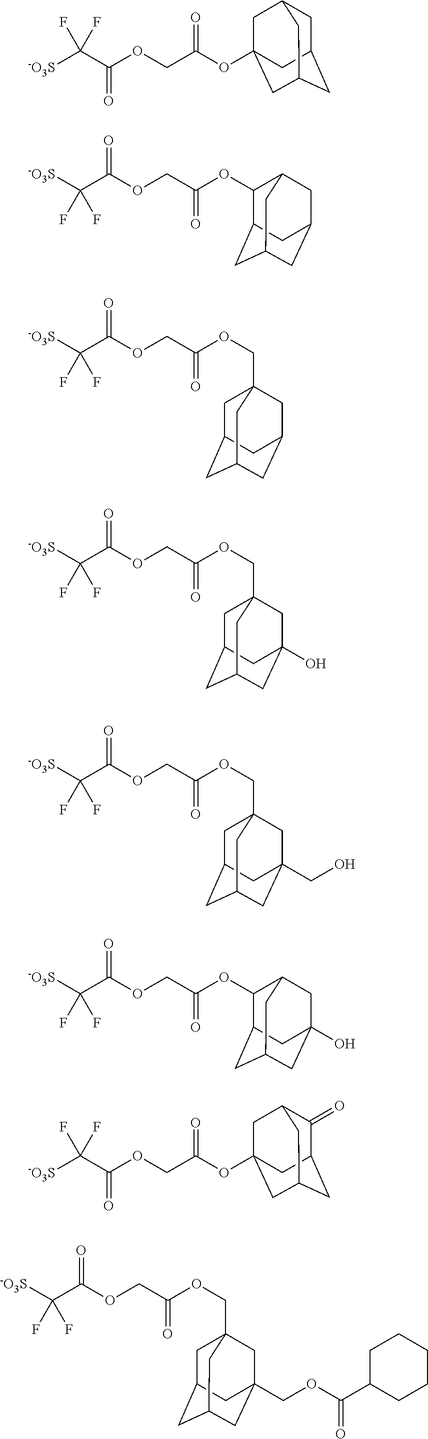

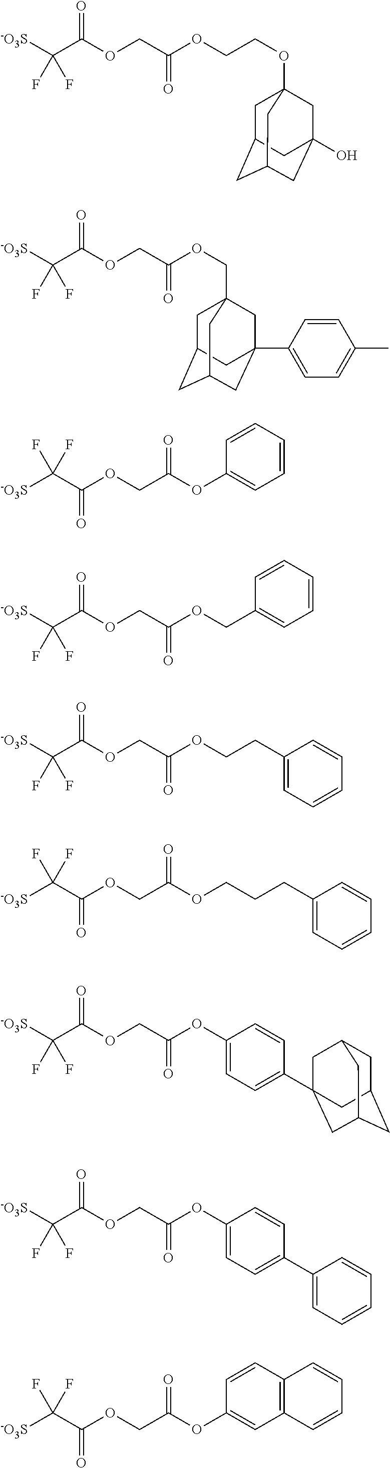

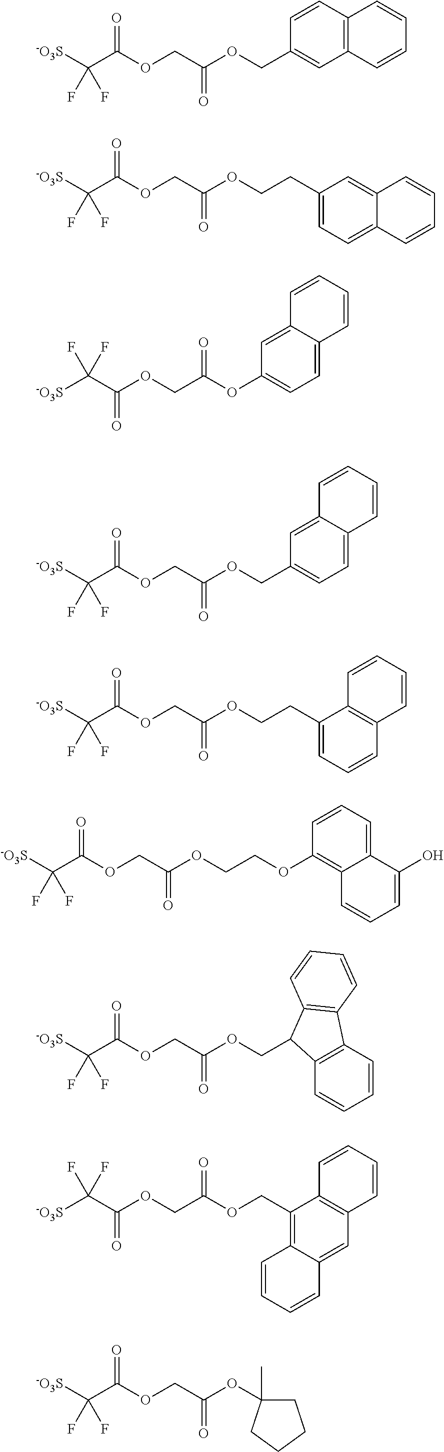

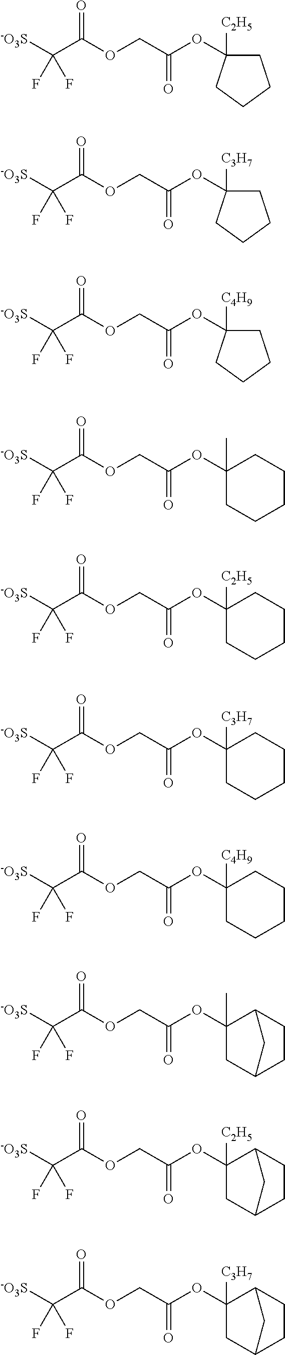

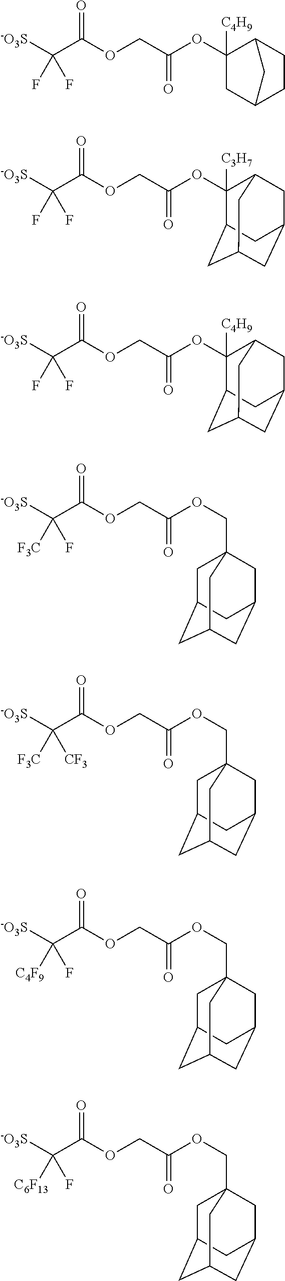

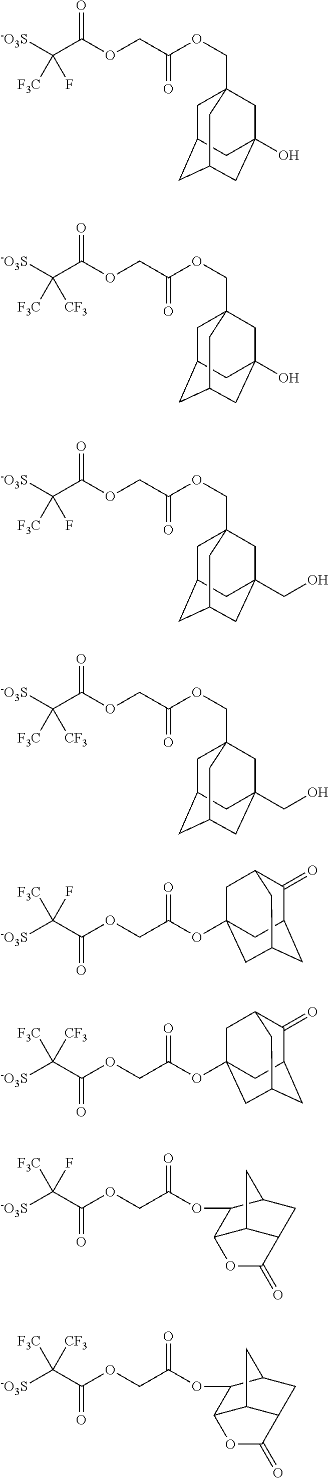

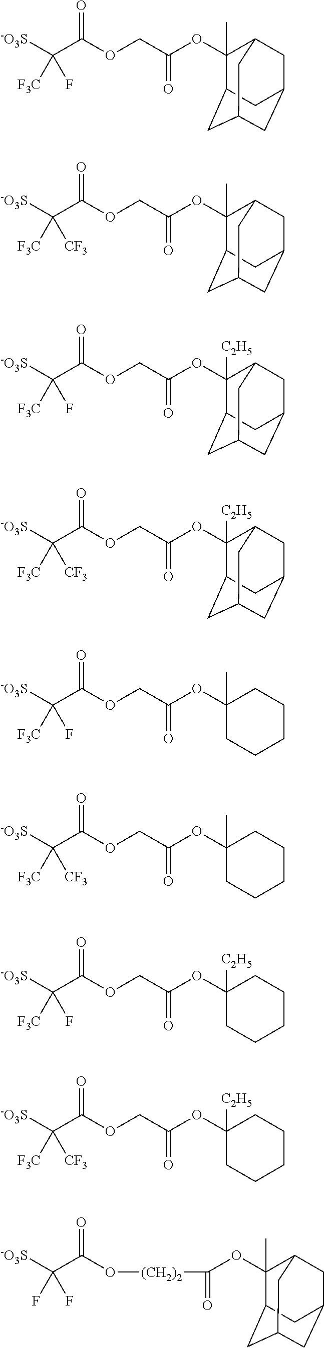

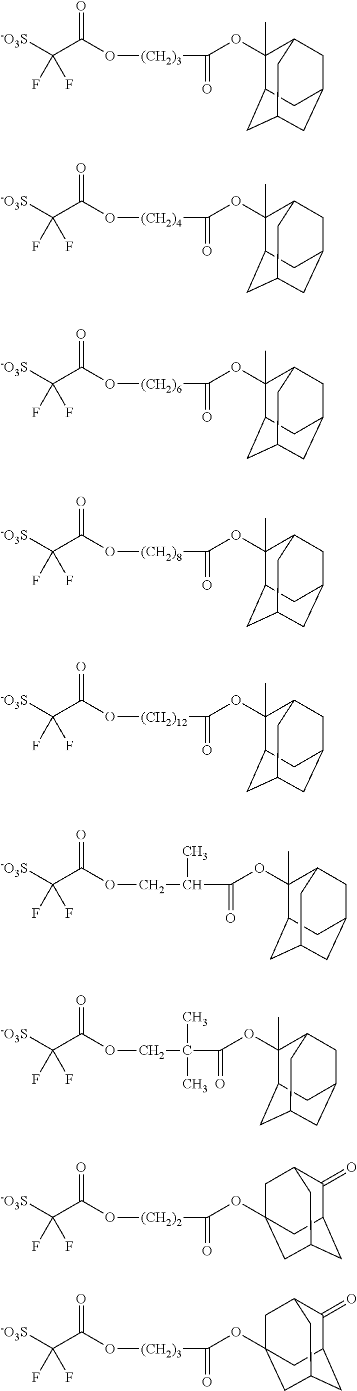

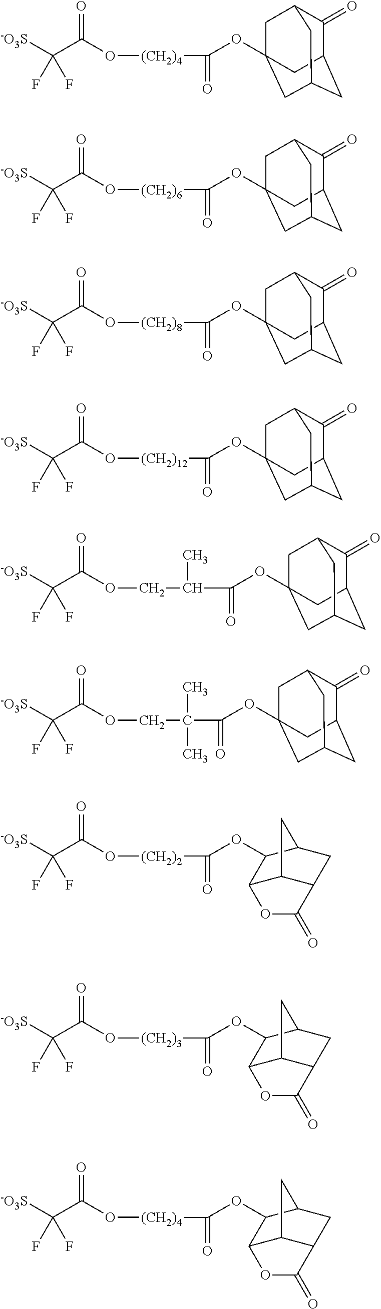

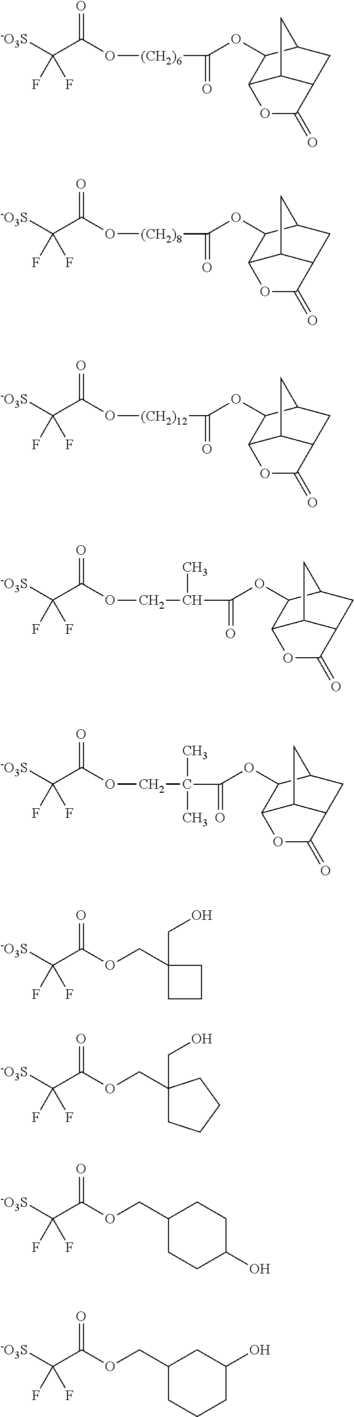

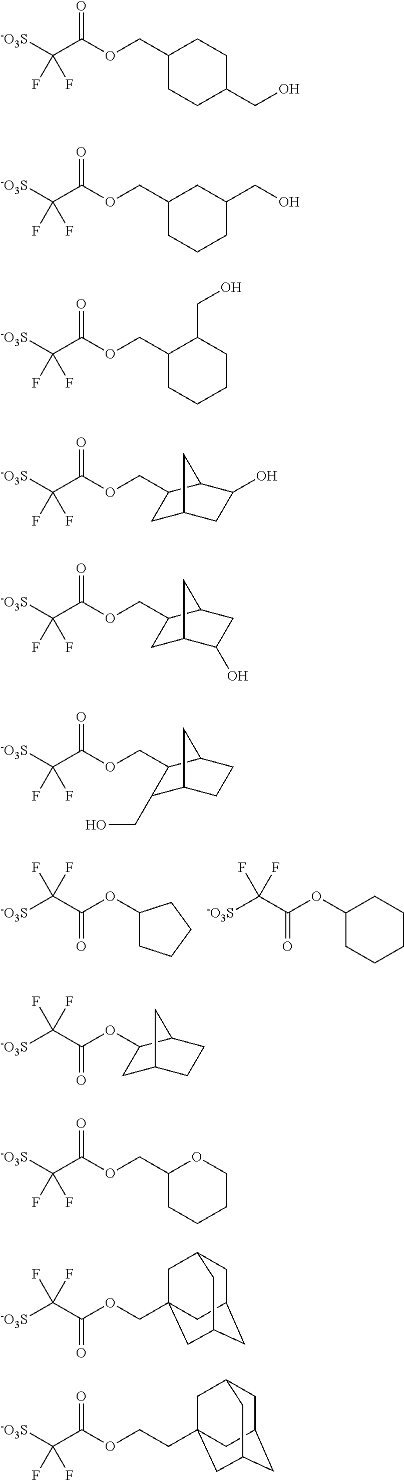

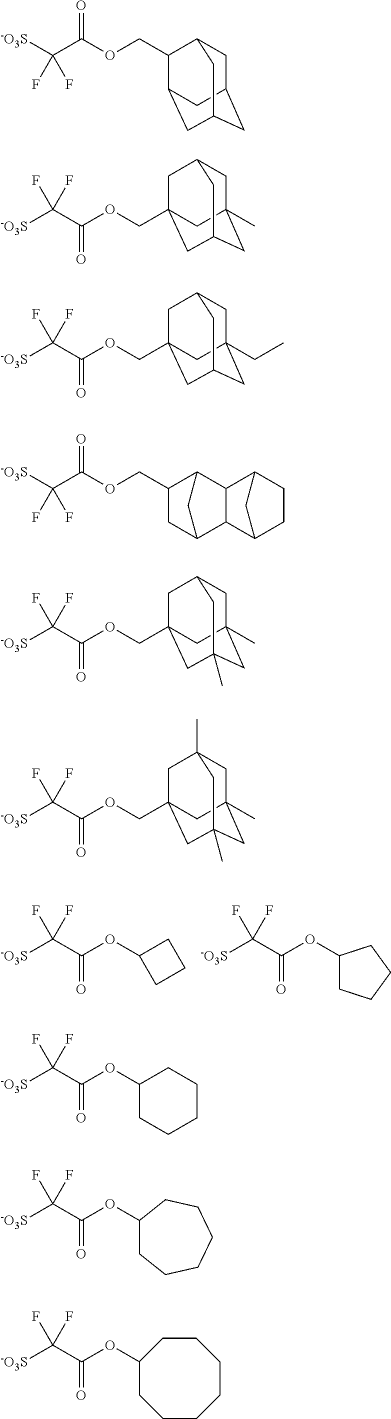

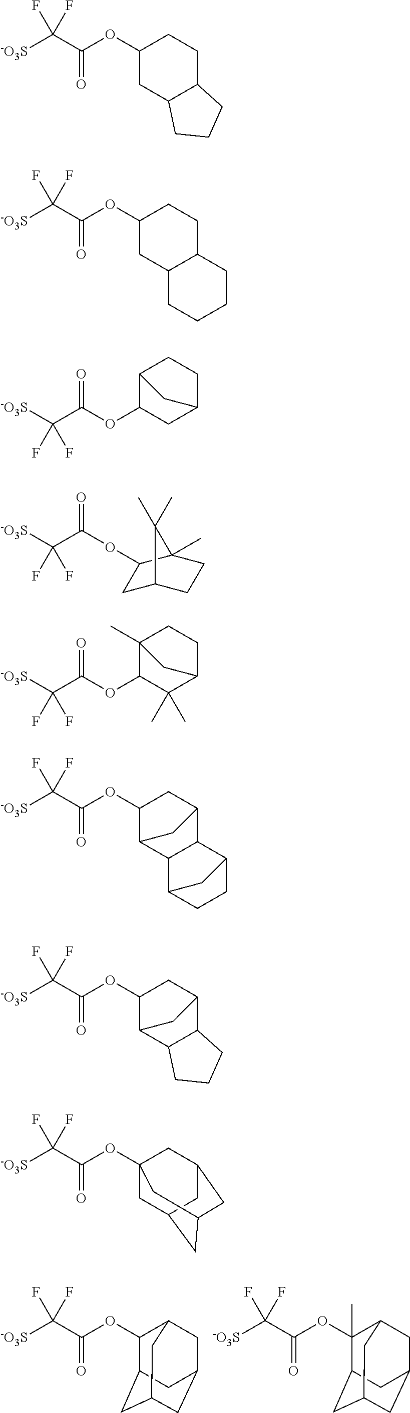

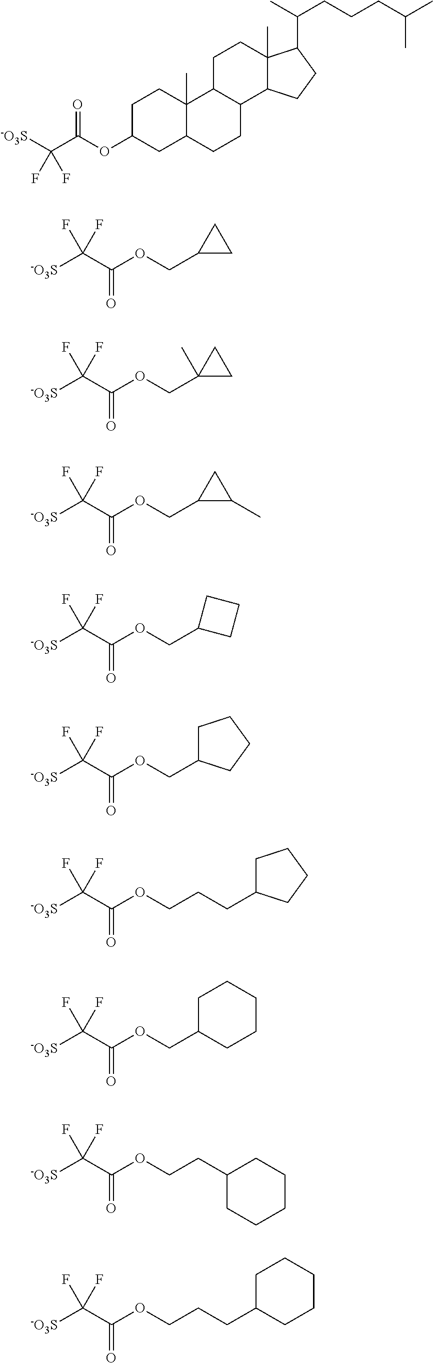

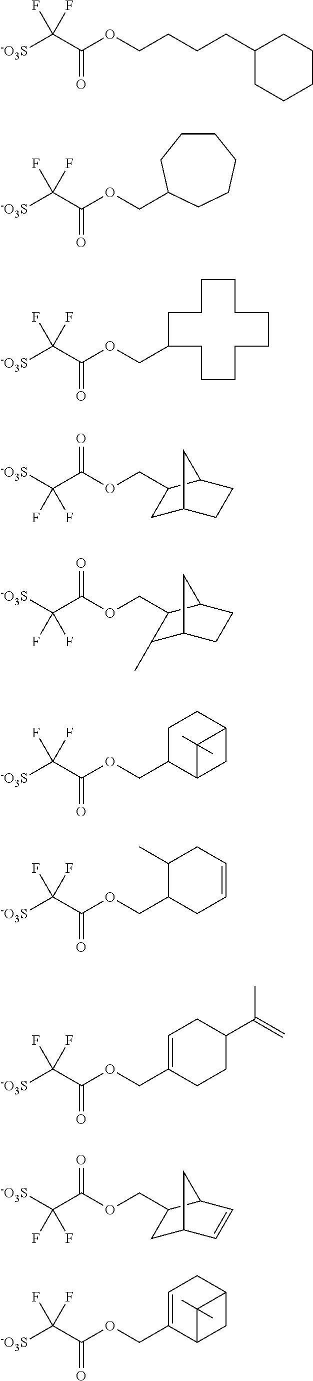

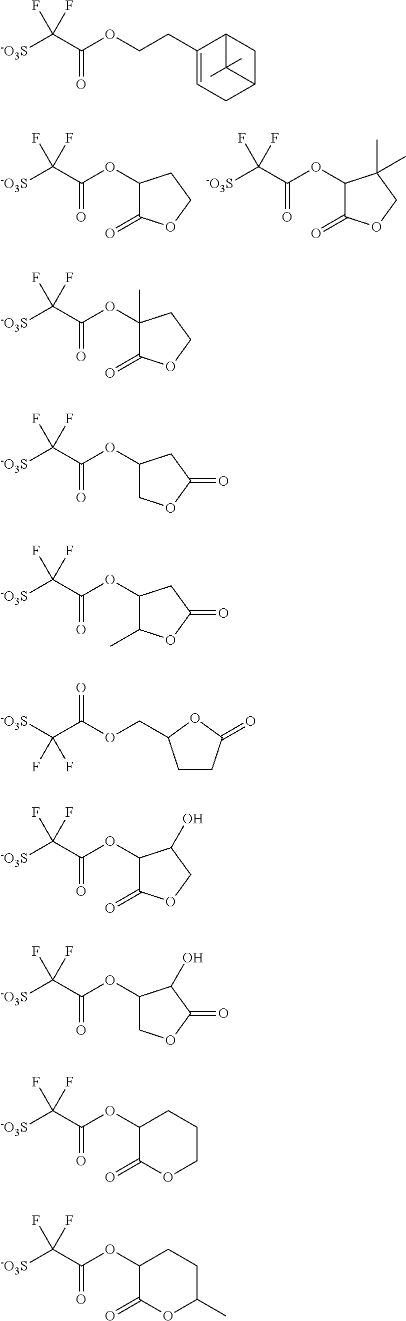

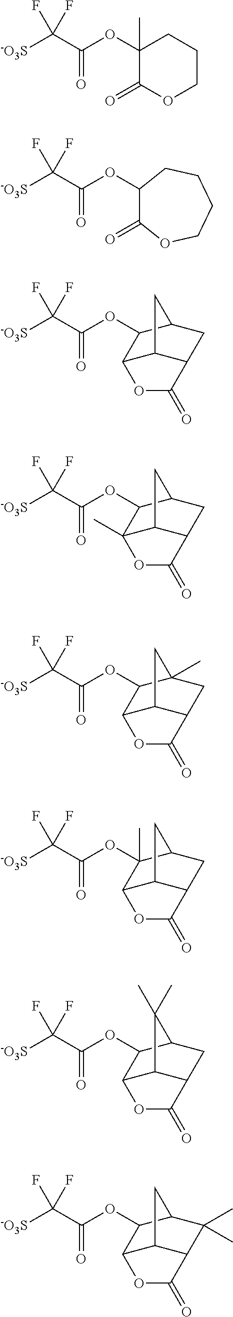

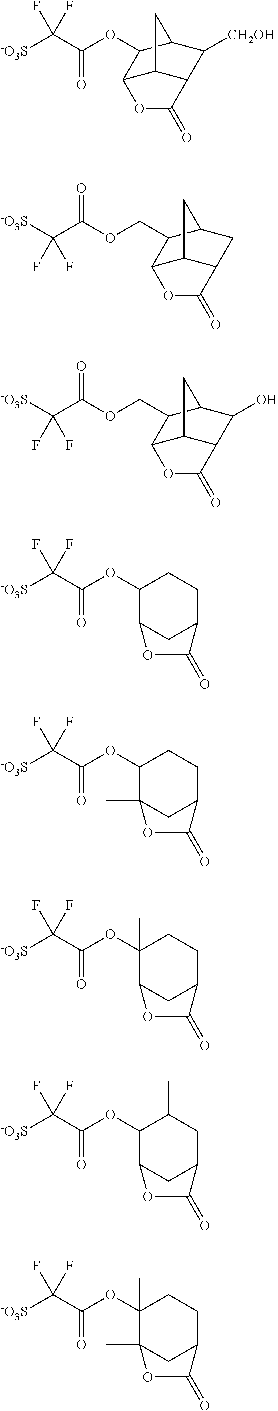

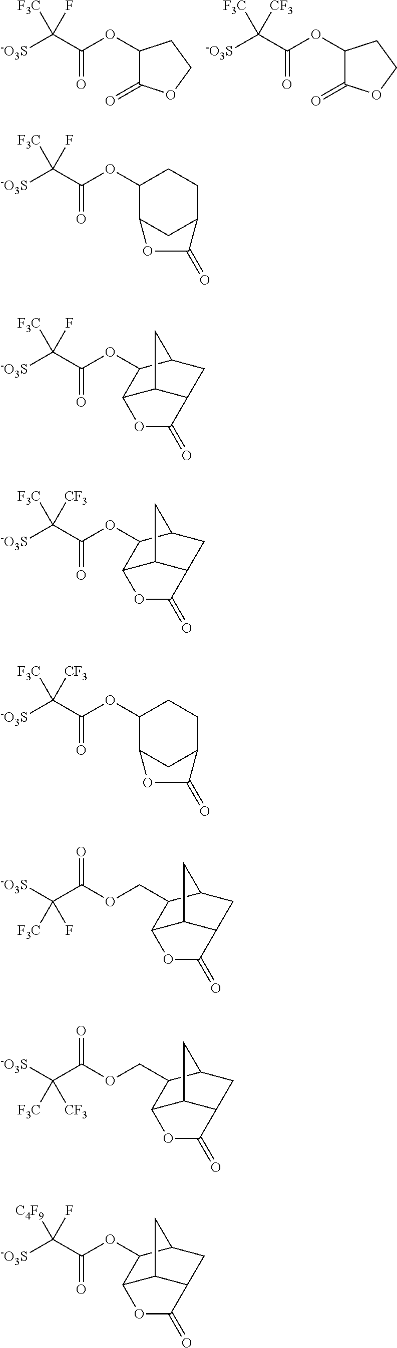

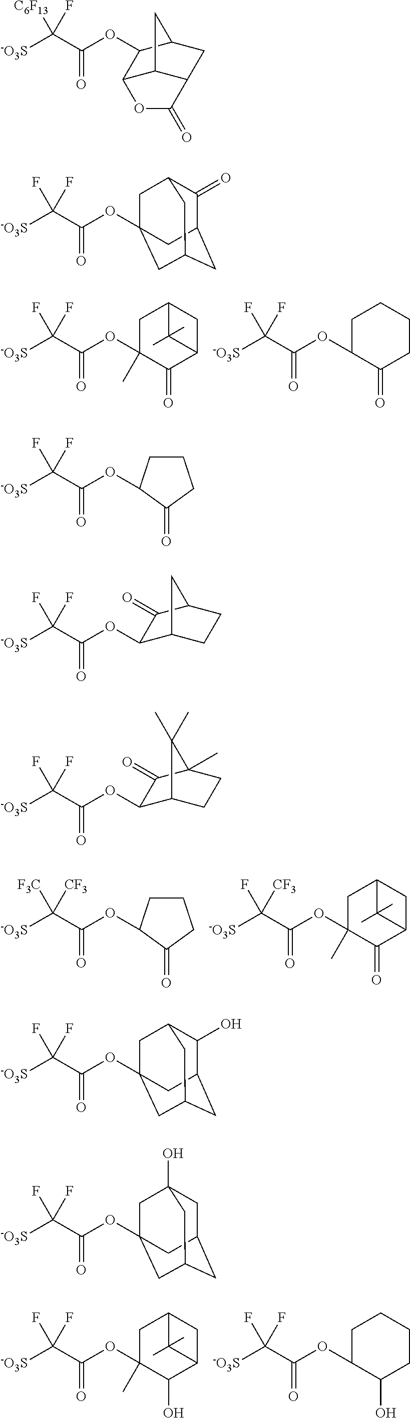

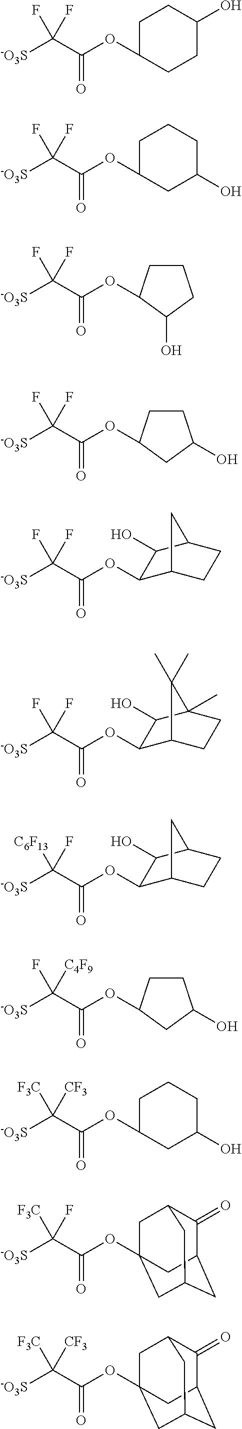

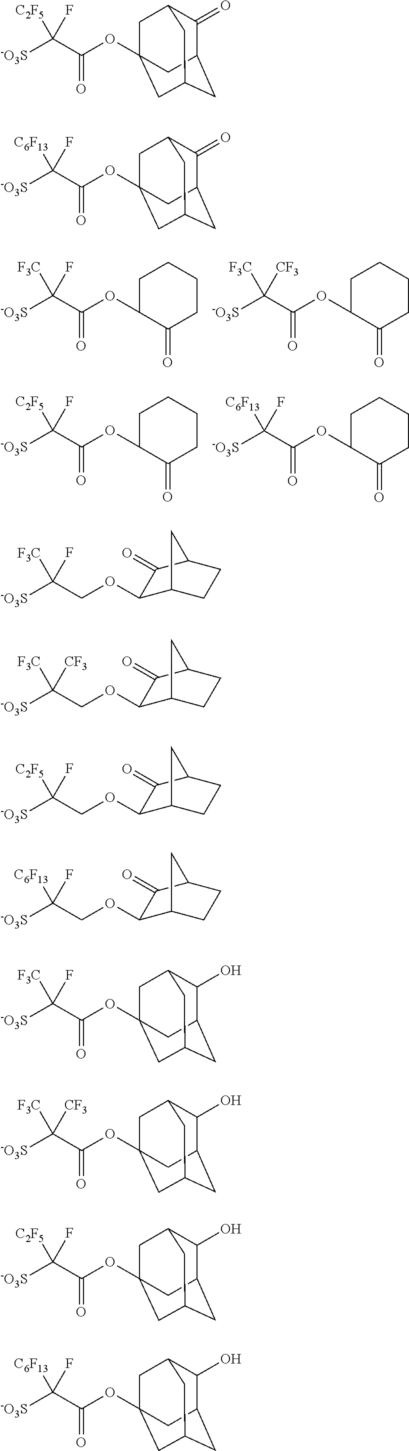

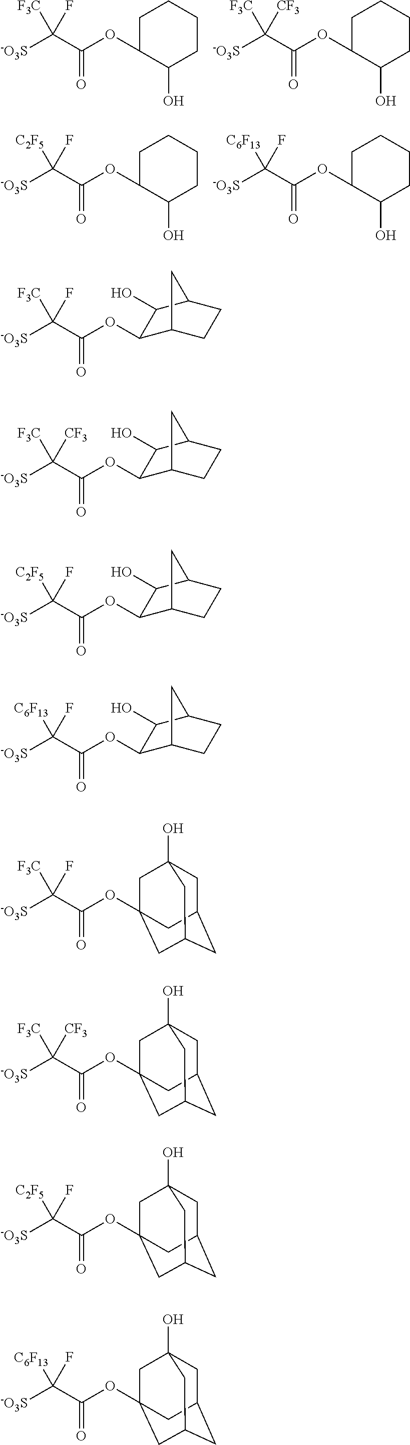

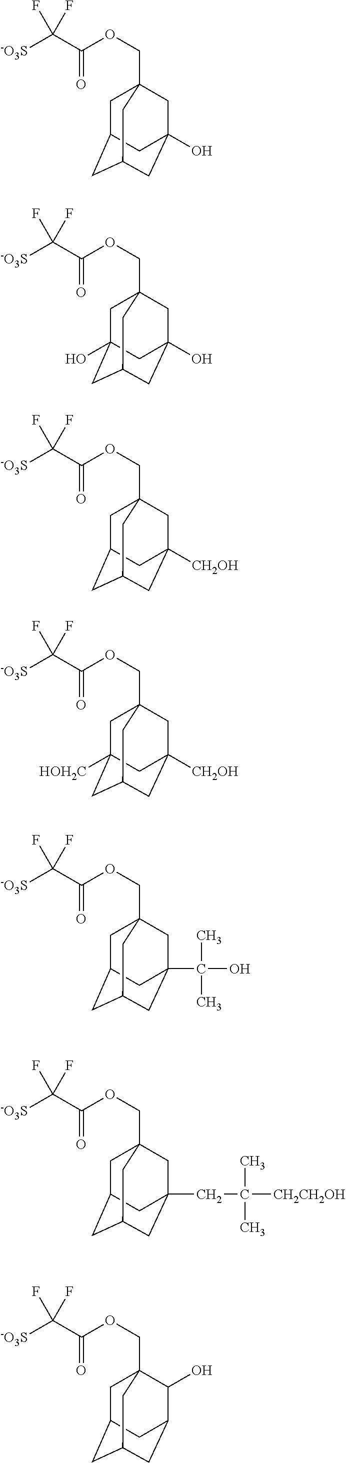

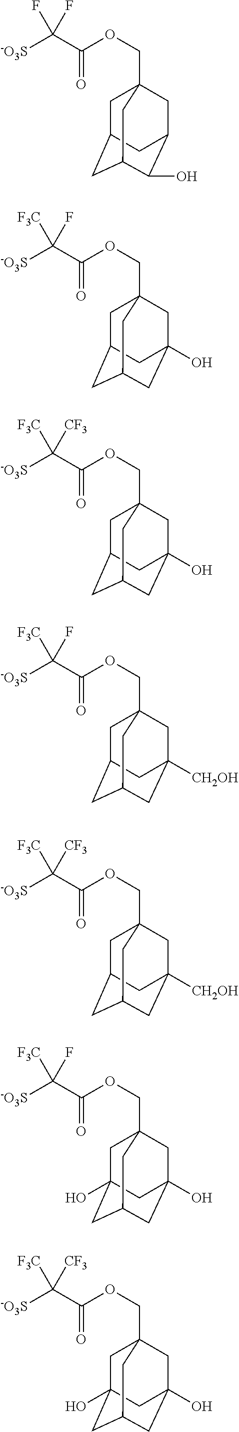

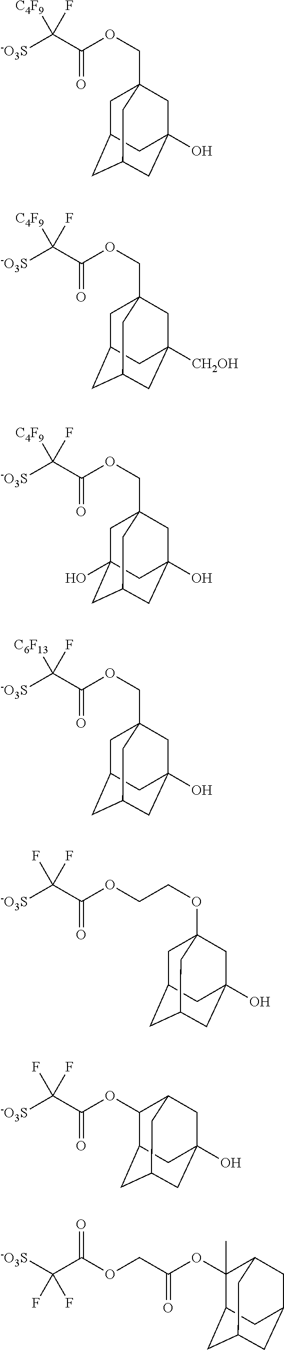

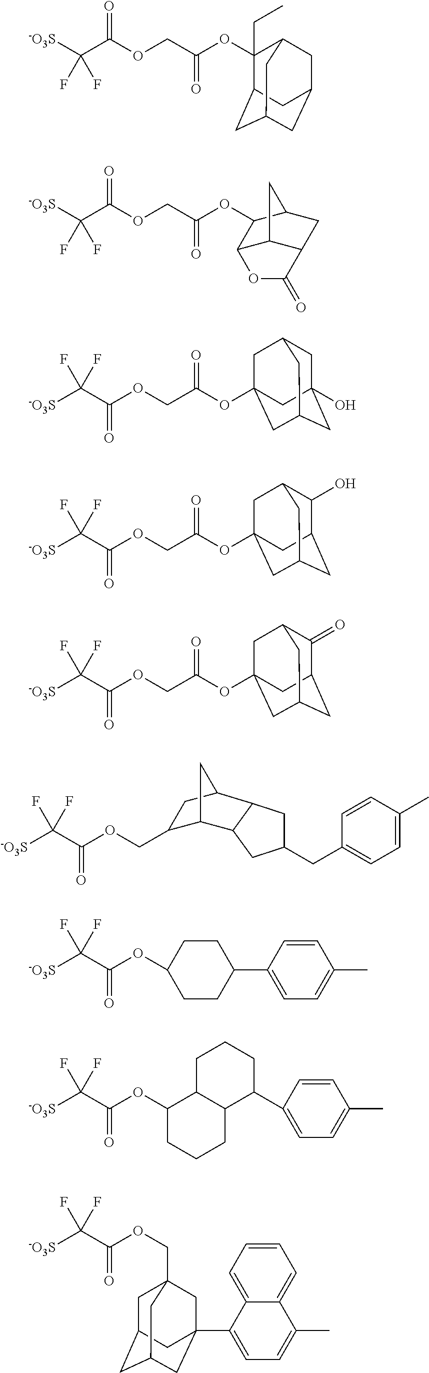

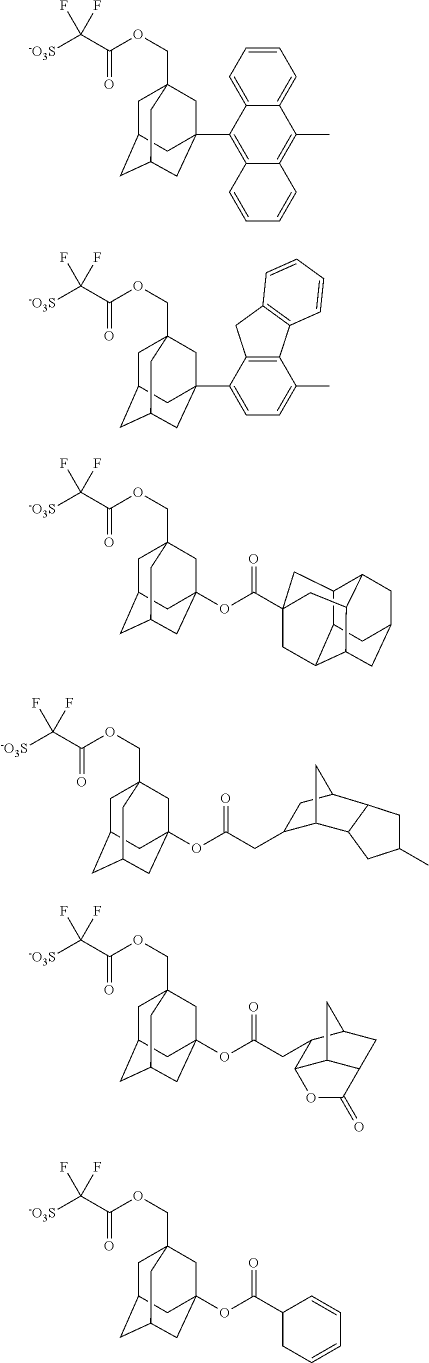

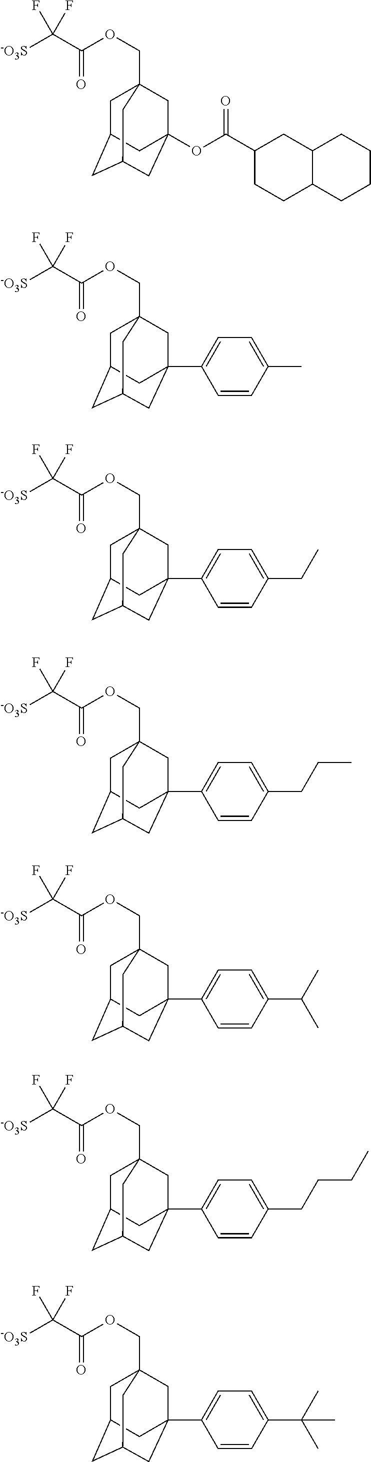

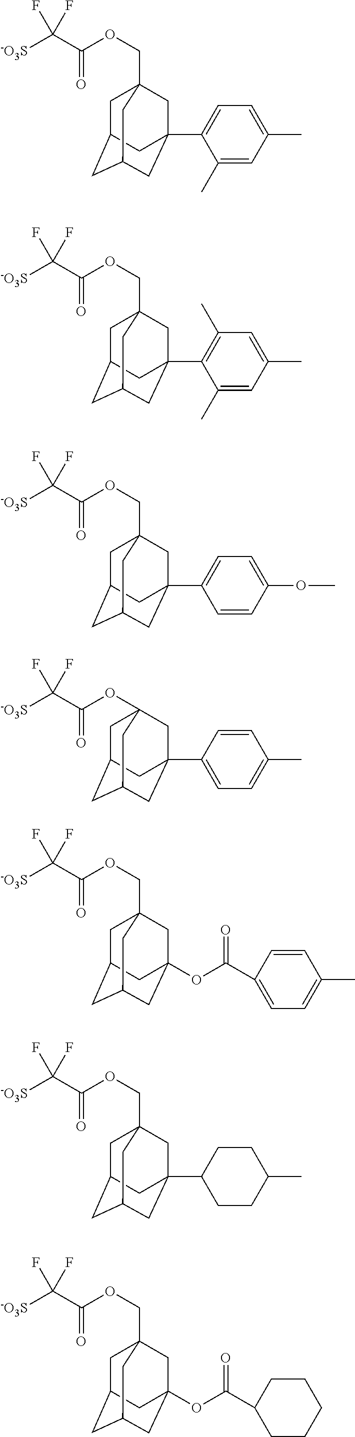

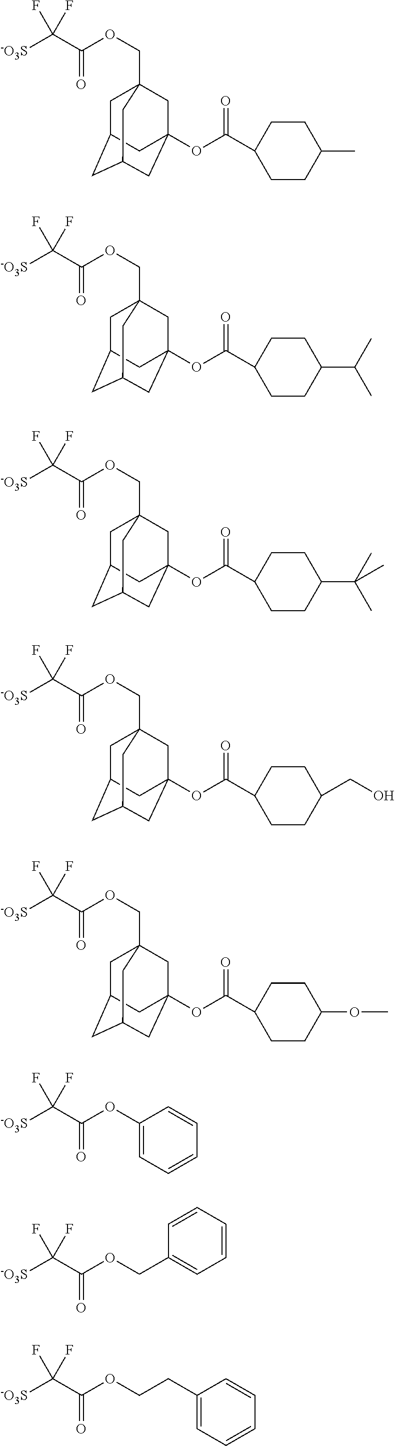

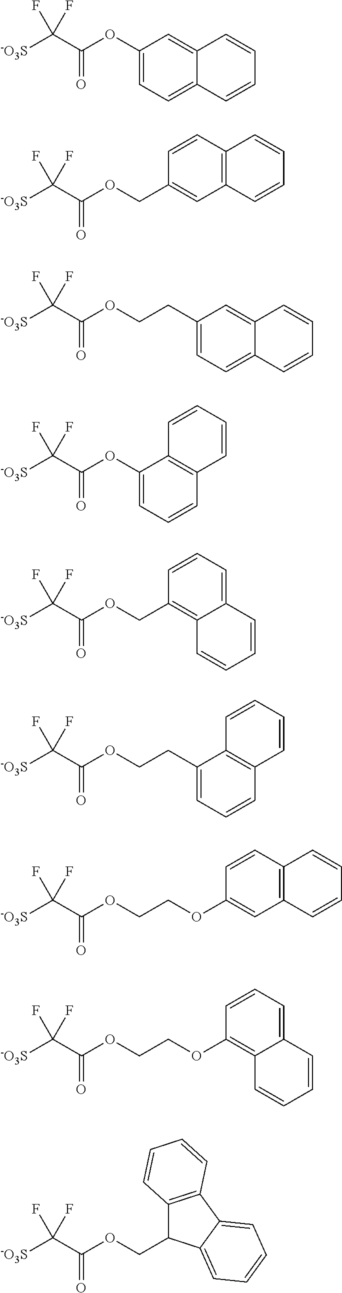

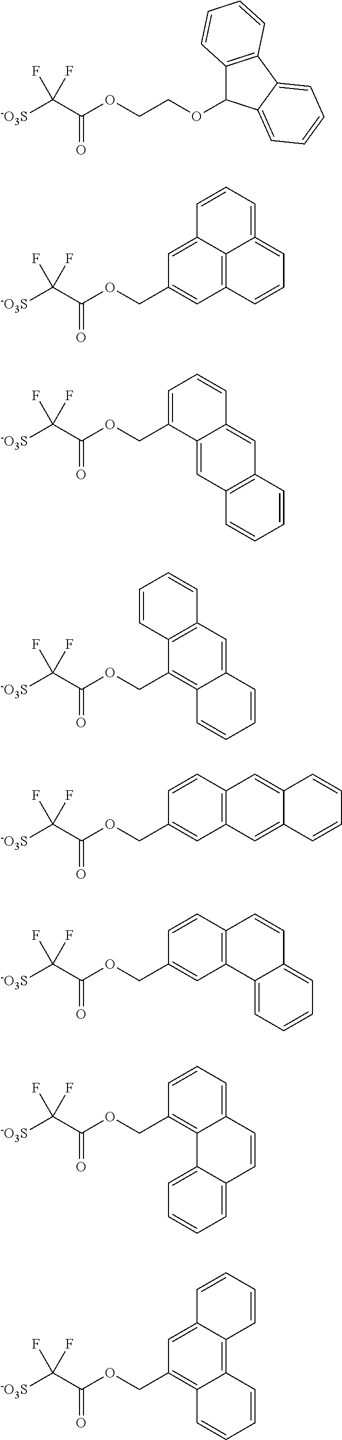

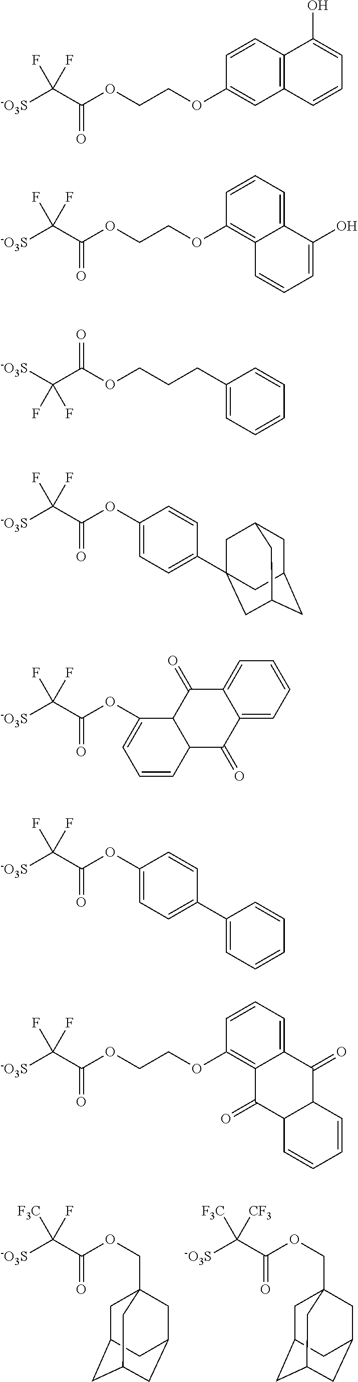

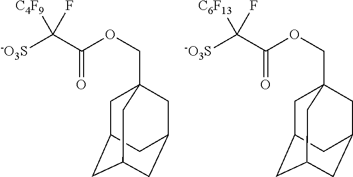

Examples of the organic counter ion represented by A⁺ include cations represented by the formulae (VIII), (IIb), (IIc) and (IId):

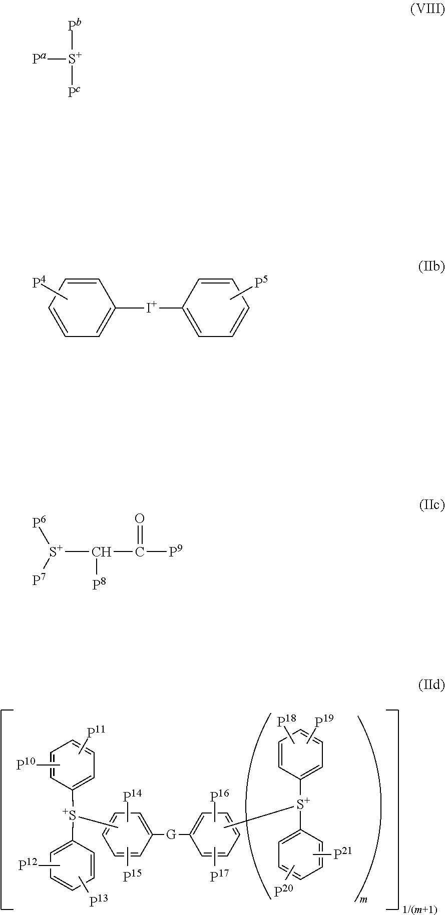

wherein P^{a}, P^{b} and P^{c} each independently represent a linear or branched chain C1-C30 alkyl group which can have one or more substituents selected from the group consisting of a hydroxyl group, a C3-C12 cyclic hydrocarbon group, a C1-C12 alkoxy group, an oxo group, a cyano group, an amino group or an amino group substituted with a C1-C4 alkyl group, or a C3-C30 cyclic hydrocarbon group which can have one or more substituents selected from the group consisting of a hydroxyl group, a C1-C12 alkoxy group, an oxo group, a cyano group, an amino group or an amino group substituted with a C1-C4 alkyl group,
P⁴ and P⁵ each independently represent a hydrogen atom, a hydroxyl group, a C1-C12 alkyl group or a C1-C12 alkoxy group,
P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group can be replaced by —CO—, —O— or —S—, P⁸ represents a hydrogen atom, P⁹ represents a C1-C12 alkyl group, a C3-C12 cycloalkyl group or a C6-C20 aromatic group which can have one or more substituents, or P⁸ and P⁹ are bonded each other to form a divalent acyclic hydrocarbon group which forms a 2-oxocycloalkyl group together with the adjacent —CHCO—, and one or more —CH₂— in the divalent acyclic hydrocarbon group can be replaced by —CO—, —O— or —S—, and
P¹⁰, P¹¹, P¹², P¹³, P¹⁴, P¹⁵, P¹⁶, P¹⁷, P¹⁸, P¹⁹, P²⁰ and P²¹ each independently represent a hydrogen atom, a hydroxyl group, a C1-C12 alkyl group or a C1-C12 alkoxy group, G represents a sulfur atom or an oxygen atom and m represents 0 or 1.

Examples of the C1-C12 alkoxy group in the formulae (VIII), (IIb) and (IId) include a methoxy group, an ethoxy group, a propoxy group, an isopropoxy group, a butoxy group, an isobutoxy group, a sec-butoxy group, a tert-butoxy group, a pentyloxy group, a hexyloxy group, an octyloxy group and a 2-ethylhexyloxy group. Examples of the C3-C12 cyclic hydrocarbon group in the formula (VIII) include a cyclopentyl group, a cyclohexyl group, a 1-adamantyl group, a 2-adamantyl group, a phenyl group, a 2-methylphenyl group, a 4-methylphenyl group, a 1-naphthyl group and a 2-naphthyl group.

Examples of the C1-C30 alkyl group which can have one or more substituents selected from the group consisting of a hydroxyl group, a C3-C12 cyclic hydrocarbon group, a C1-C12 alkoxy group, an oxo group, a cyano group, an amino group or an amino group substituted with a C1-C4 alkyl group in the formula (VIII) include a methyl group, an ethyl group, a propyl group, an isopropyl group, a butyl group, an isobutyl group, a sec-butyl group, a tert-butyl group, a pentyl group, a hexyl group, an octyl group, a 2-ethylhexyl group and a benzyl group.

Examples of the C3-C30 cyclic hydrocarbon group which can have one or more substituents selected from the group consisting of a hydroxyl group, a C1-C12 alkoxy group, an oxo group, a cyano group, an amino group or an amino group substituted with a C1-C4 alkyl group in the formula (VIII) include a cyclopentyl group, a cyclohexyl group, a 1-adamantyl group, a 2-adamantyl group, a bicyclohexyl group, a phenyl group, a 2-methylphenyl group, a 4-methylphenyl group, a 4-ethylphenyl group, a 4-isopropylphenyl group, a 4-tert-butylphenyl group, a 2,4-dimethylphenyl group, a 2,4,6-trimethylphenyl group, a 4-hexylphenyl group, a 4-octylphenyl group, a 1-naphthyl group, a 2-naphthyl group, a fluorenyl group, a 4-phenylphenyl group, a 4-hydroxyphenyl group, a 4-methoxyphenyl group, a 4-tert-butoxyphenyl group and a 4-hexyloxyphenyl group.

Examples of the C1-C12 alkyl group in the formulae (IIb), (IIc) and (IId) include a methyl group, an ethyl group, a propyl group, an isopropyl group, a butyl group, an isobutyl group, a sec-butyl group, a tert-butyl group, a pentyl group, a hexyl group, an octyl group and a 2-ethylhexyl group.

Examples of the C3-C12 cycloalkyl group in the formula (IIc) include a cyclopropyl group, a cyclobutyl group, a cyclopentyl group, a cyclohexyl group, a cycloheptyl group, a cyclooctyl group and a cyclodecyl group. Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and an oxybisethylenesulfonio group.

Examples of the C6-C20 aromatic group which can have one or more substituents in the formula (IIc) include a phenyl group, a tolyl group, a xylyl group, a tert-butylphenyl group and a naphthyl group. Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include a 2-oxocyclopentyl group and a 2-oxocyclohexyl group.

The cation represented by the formula (VIII) is preferable and a cation represented by the formula (IIa):

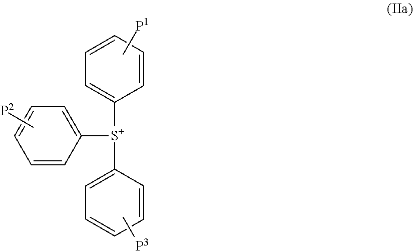

wherein P¹, P² and P³ each independently represent a hydrogen atom, a hydroxyl group, a C1-C12 alkyl group, a C1-C12 alkoxy group, a cyano group or an amino group, is preferable, and a cation represented by the formula (IIe):

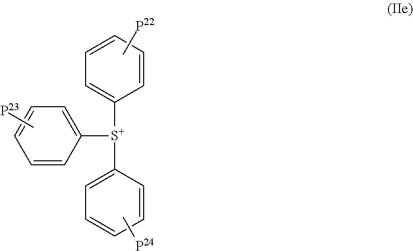

wherein P²², P²³ and P²⁴ each independently represents a hydrogen atom, a hydroxyl group or a C1-C4 alkyl group, is more preferable.

In the formula (IIa), examples of the C1-C12 alkyl group include a methyl group, an ethyl group, a propyl group, an isopropyl group, a butyl group, an isobutyl group, a sec-butyl group, a tert-butyl group, a pentyl group, a hexyl group, an octyl group and a 2-ethylhexyl group. Examples of the C1-C12 alkoxy group include a methoxy group, an ethoxy group, a propoxy group, a butoxy group, a hexyloxy group, an octyloxy group and a 2-ethylhexyloxy group.

Examples of the cations represented by the formulae (VIII), (IIa) and (IIe) include the followings.

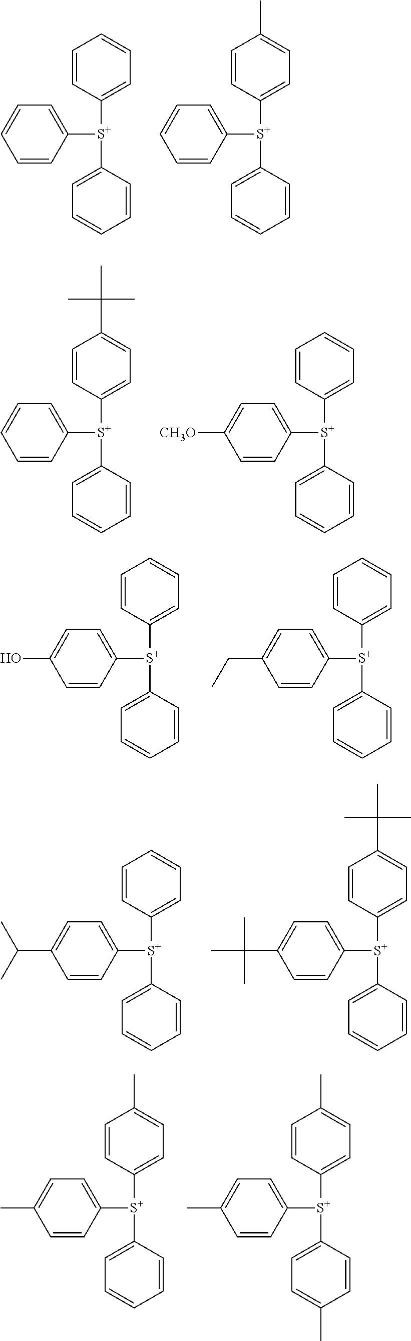

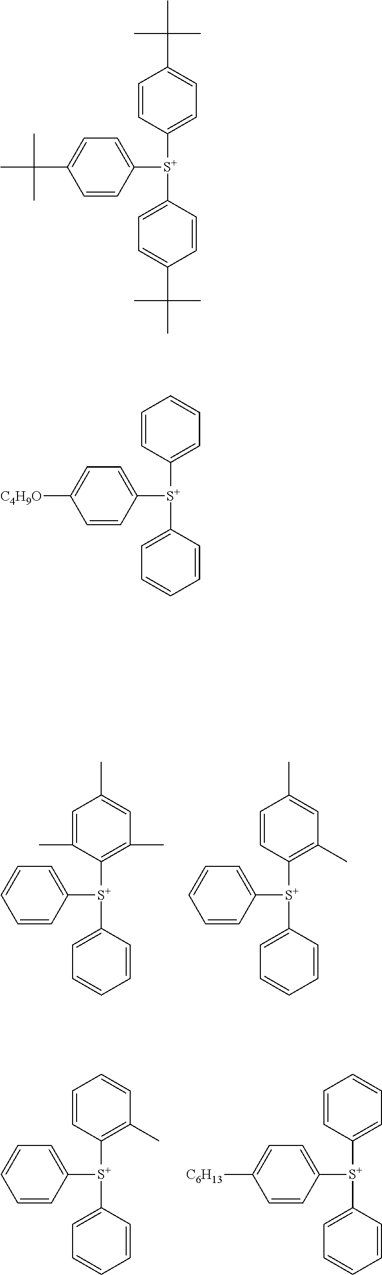

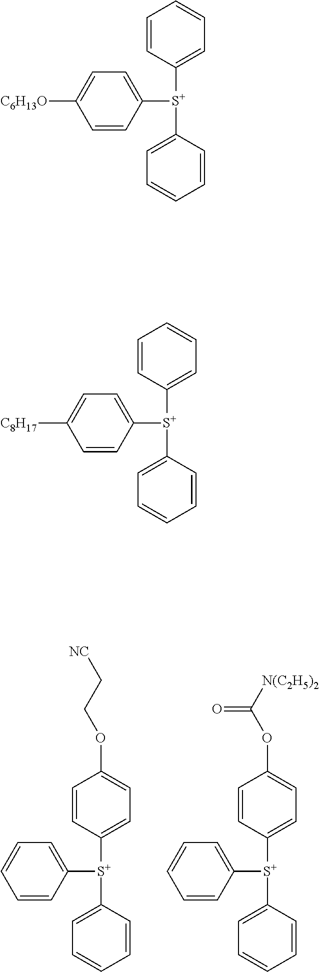

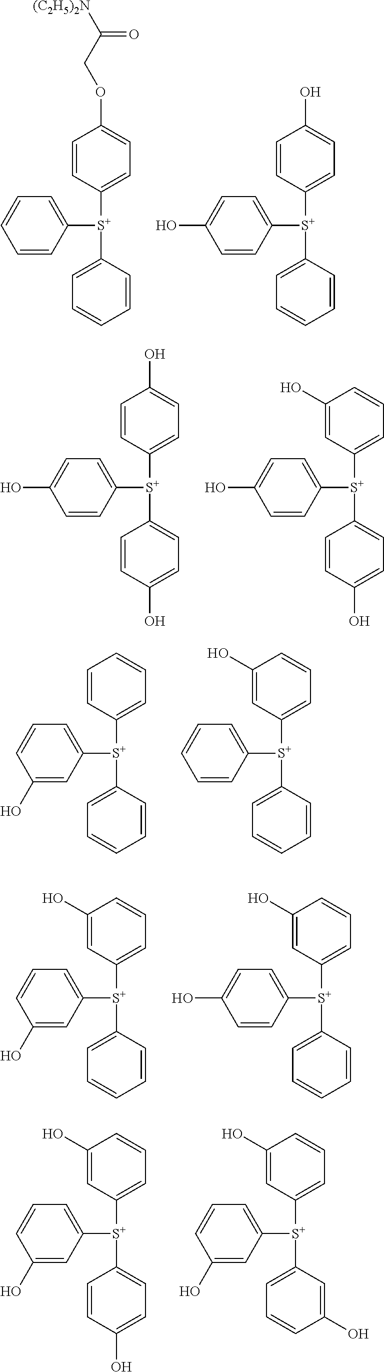

Examples of the cation represented by the formula (IIb) include the followings.

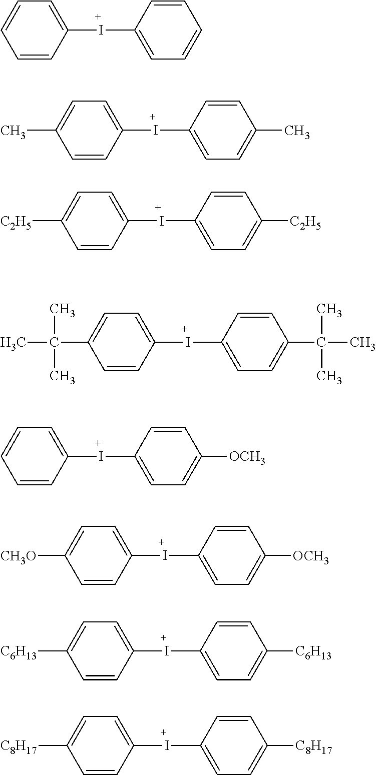

Examples of the cation represented by the formula (IIc) include the followings.

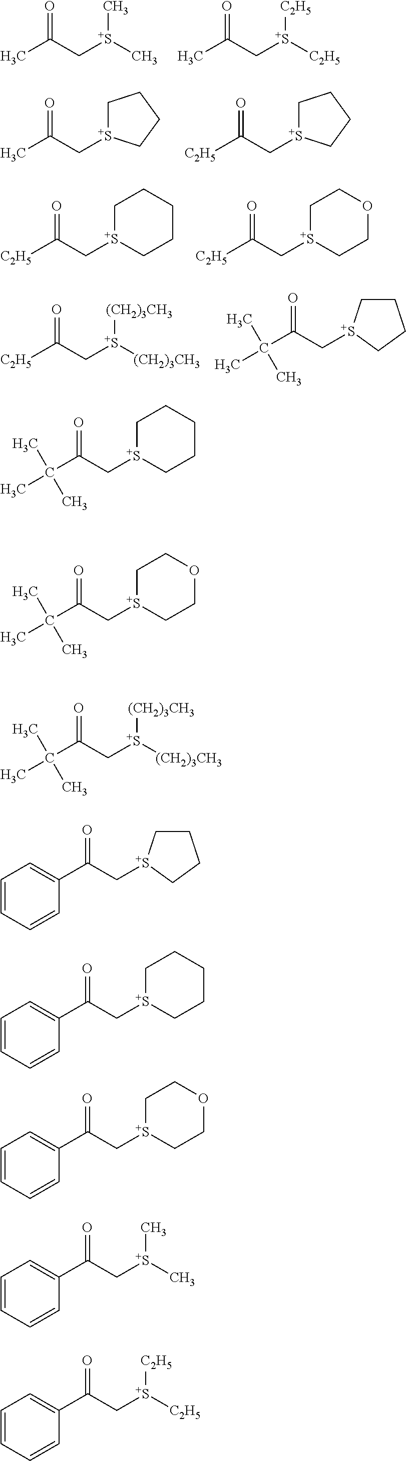

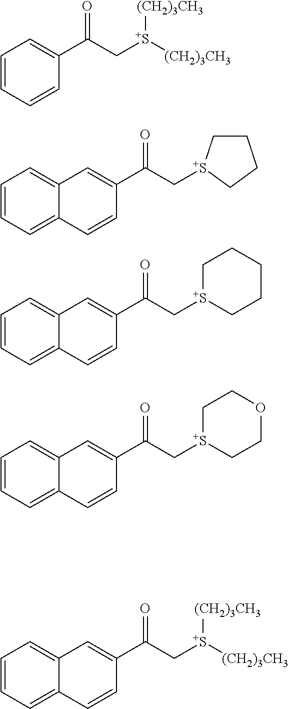

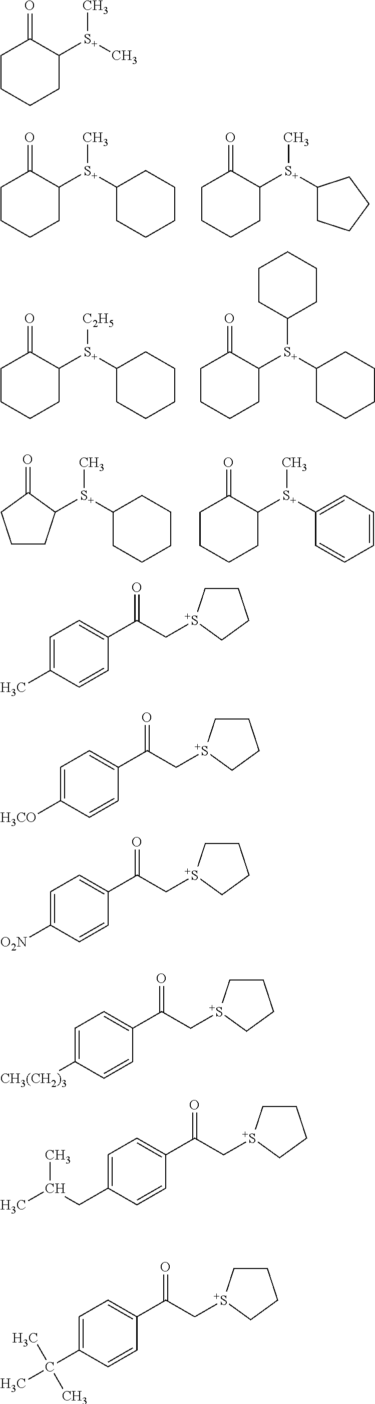

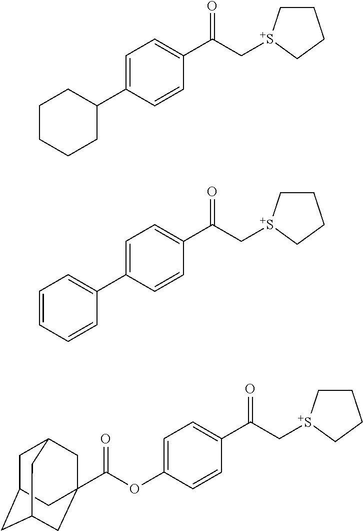

Examples of the cation represented by the formula (IId) include the followings.

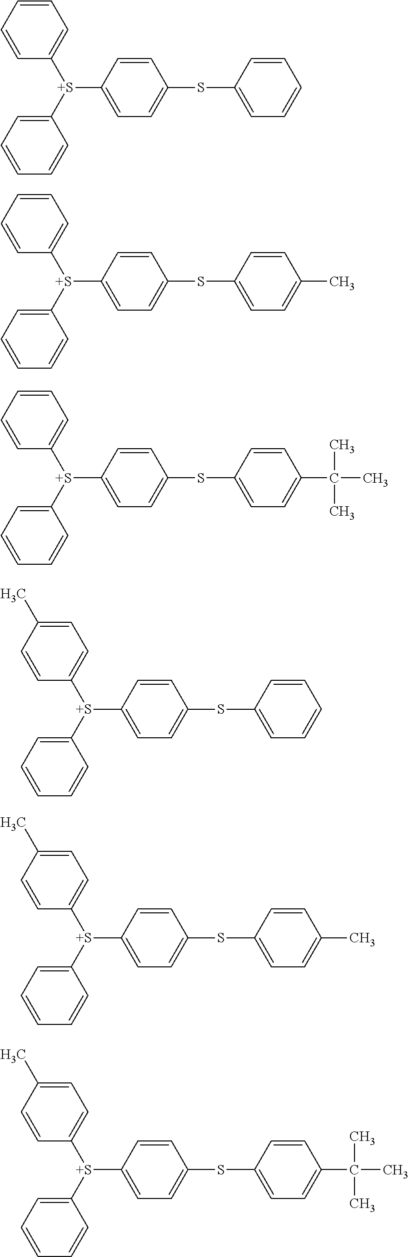

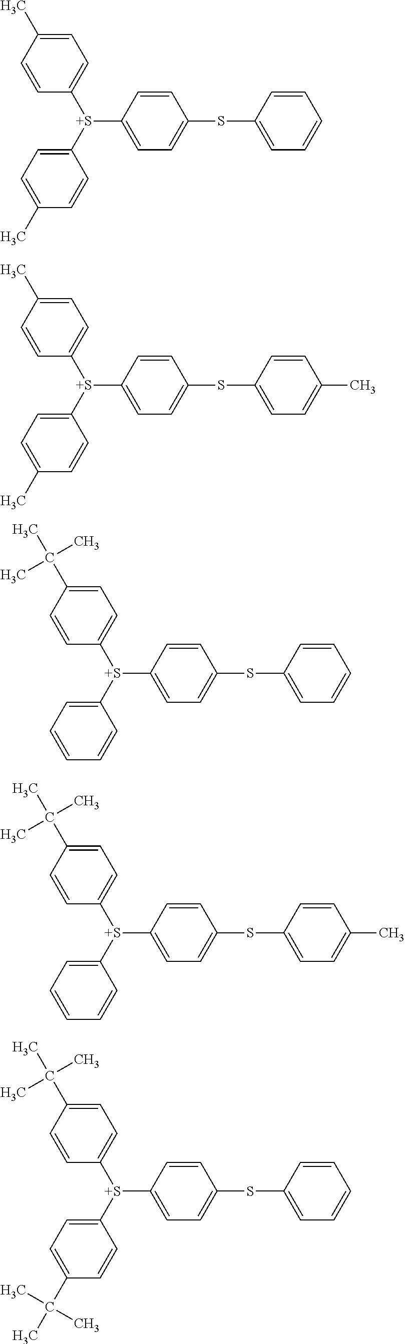

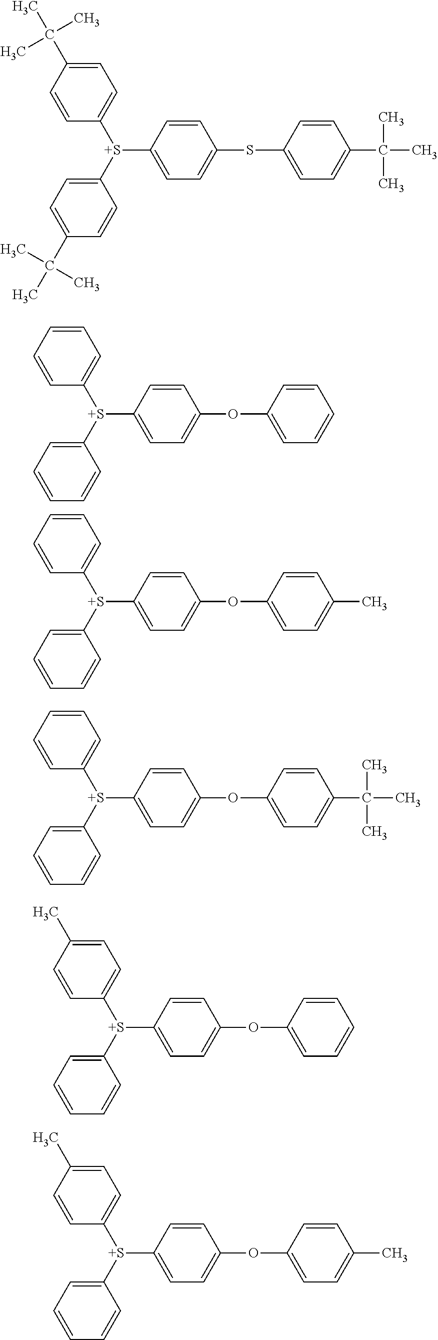

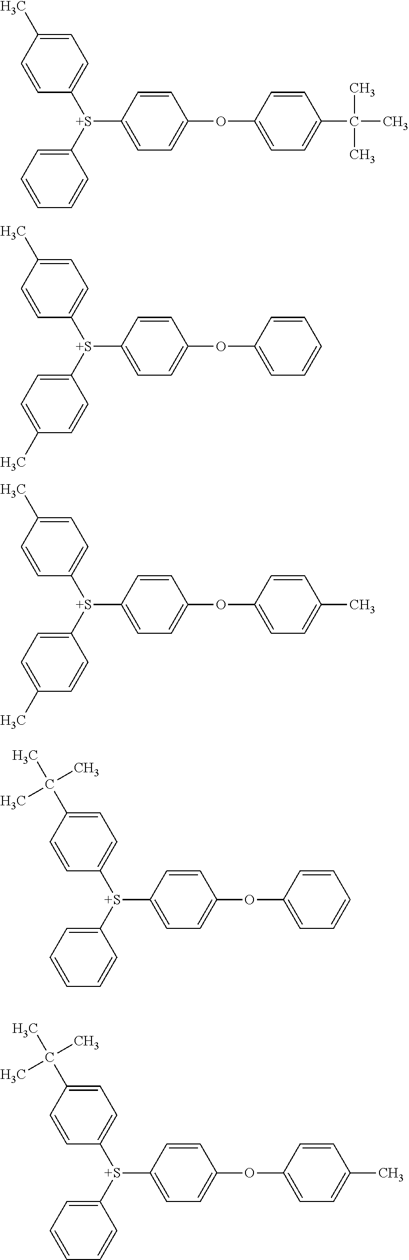

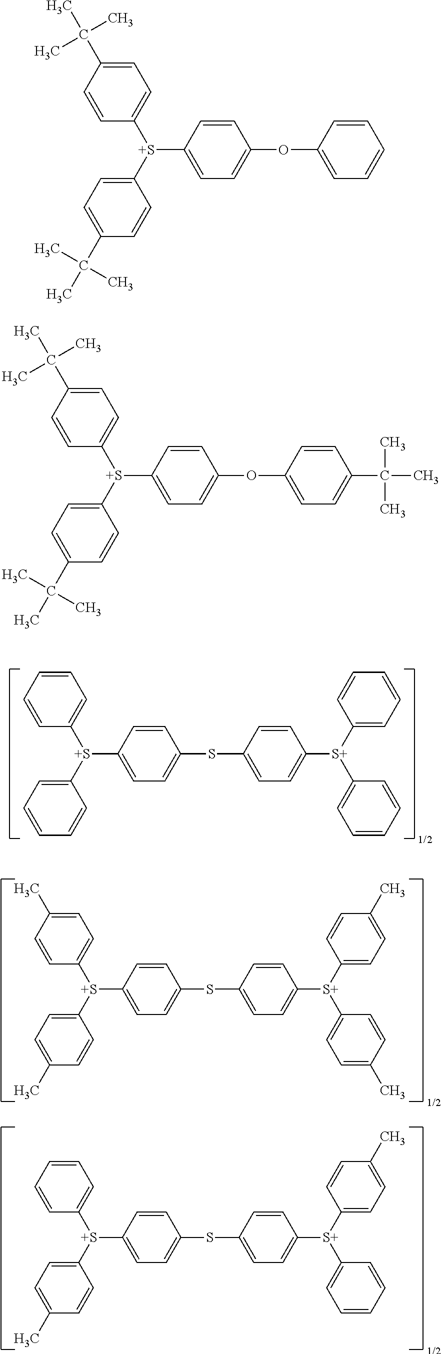

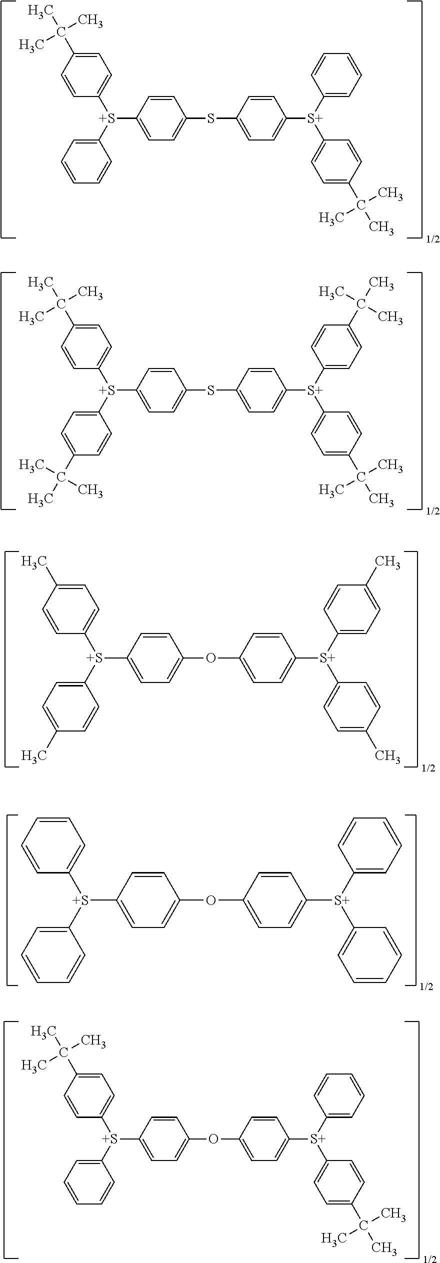

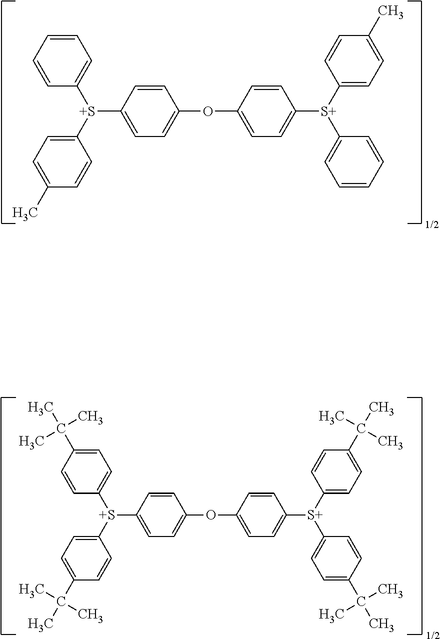

From the view point of resolution of the photoresist composition and pattern profile obtained, salts represented by the formulae (IXa), (IXb), (IXc), (IXd) and (IXe):

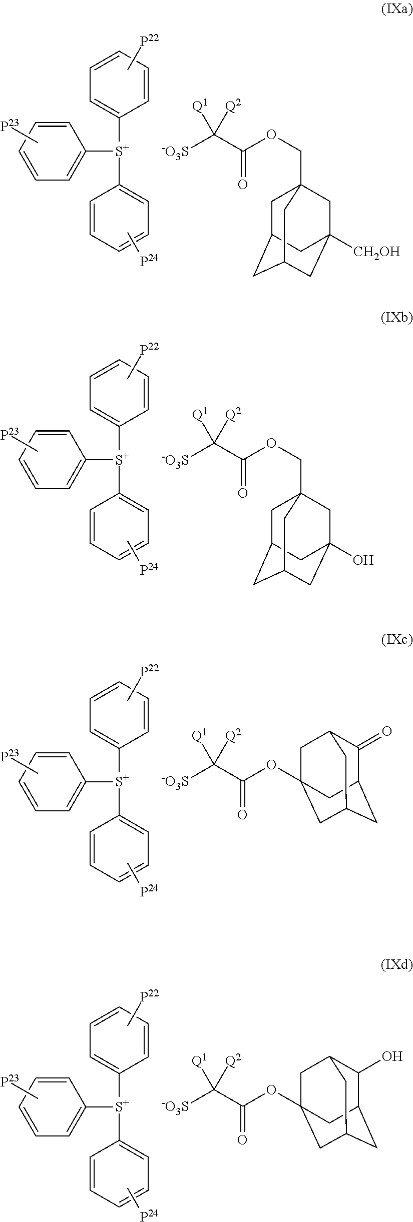

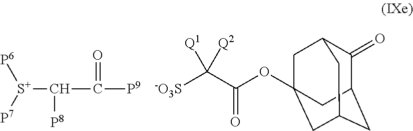

wherein P⁶, P⁷, P⁸, P⁹, P²², P²³, P²⁴, P²⁵, P²⁶, P²⁷, Q¹ and Q² are the same meanings as defined above, are preferable as the acid generator.

Among them, the following salts are more preferable because of easy production thereof.

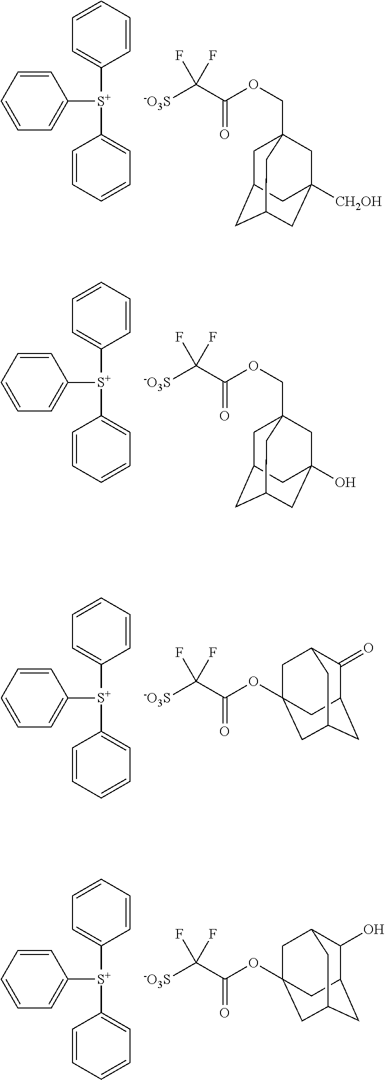

These salts used as the acid generator can be produced according to the method described in JP 2006-257078 A.

As the acid generator, a salt represented by the formula (VII):

A^{+-O}₃S—R^{b1} (VII)

wherein R^{b1} represents a C1-C6 alkyl group or a C1-C6 perfluoroalkyl group, and A⁺ is the same as defined above, can also be used.

R^{b1} is preferably a C1-C6 perfluoroalkyl group.

Examples of the anion of the salt represented by the formula (VII) include a trifluoromethanosulfonate, a pentafluoroethanesulfonate, a heptafluoropropanesulfonate and a nonafluorobutanesulfonate.

Examples of the other acid generator include the followings.

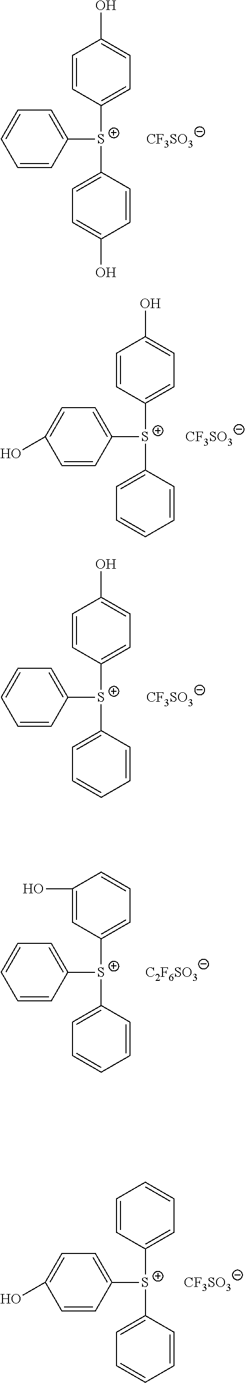

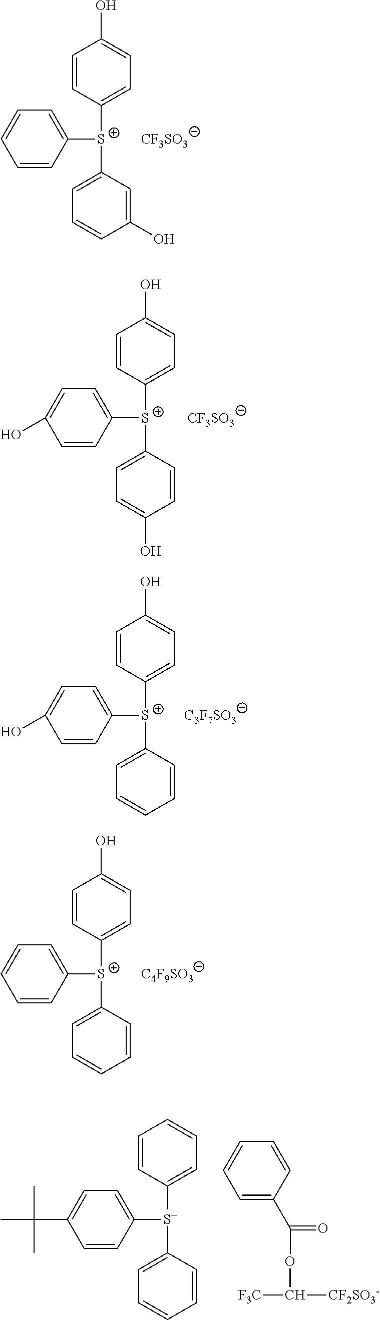

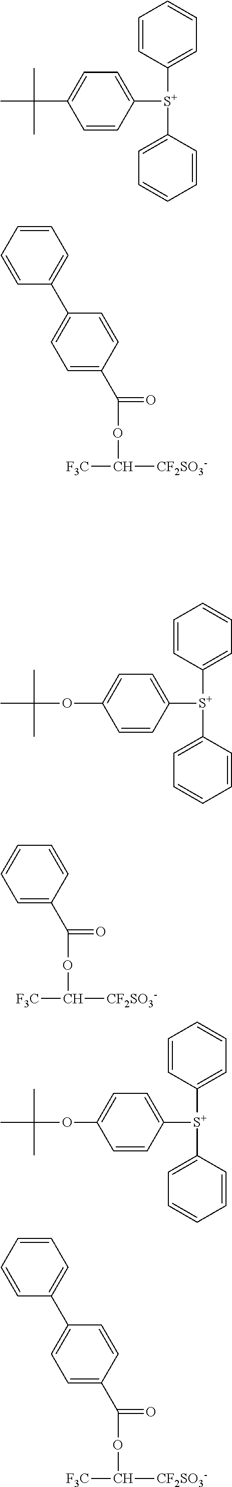

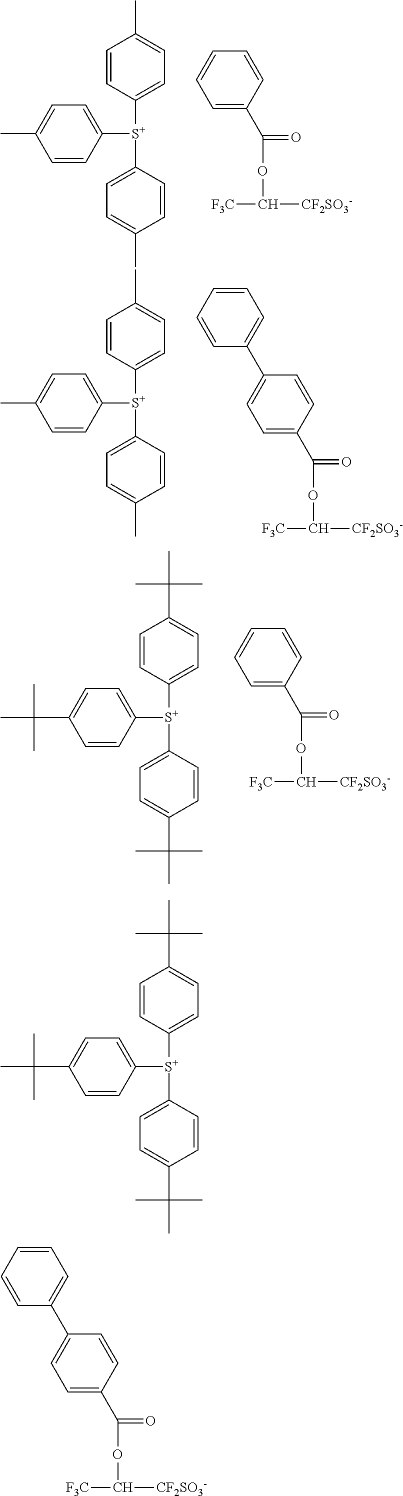

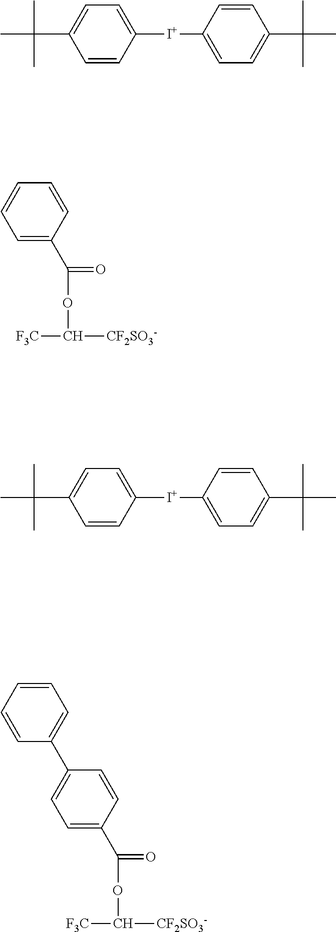

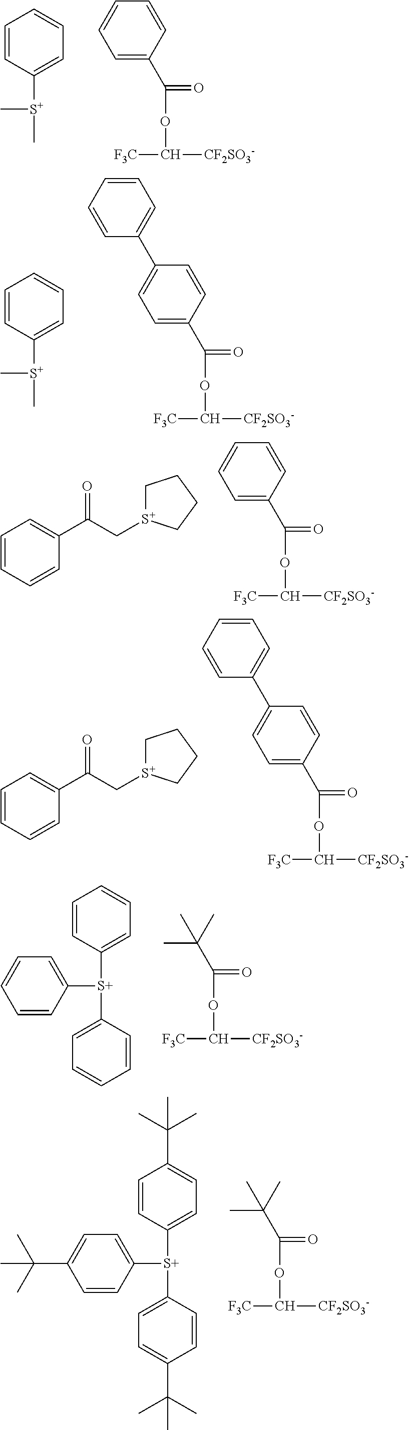

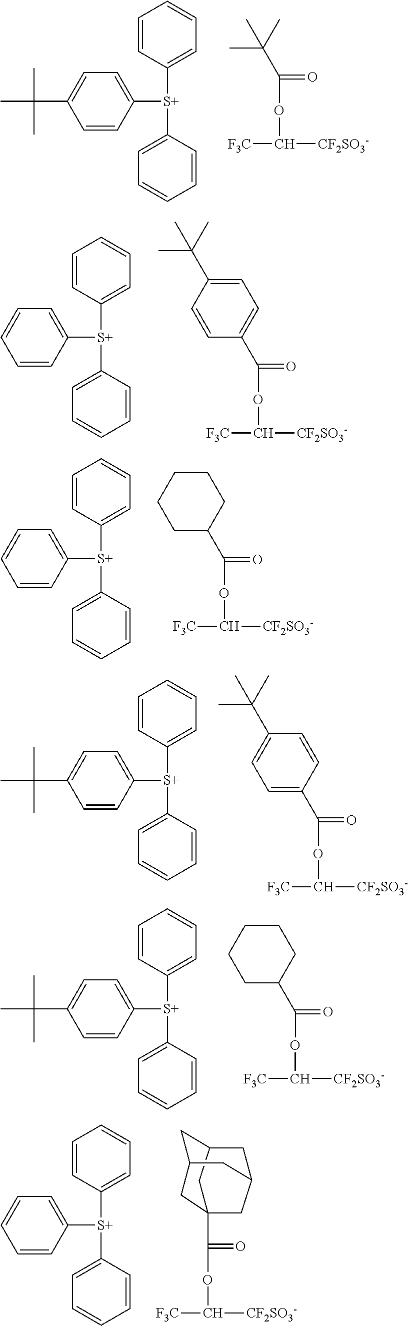

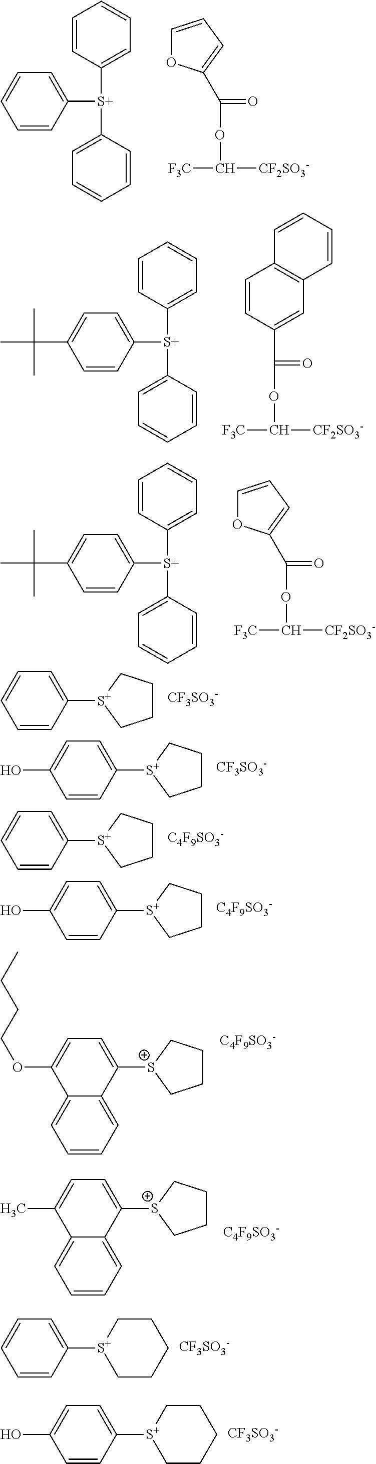

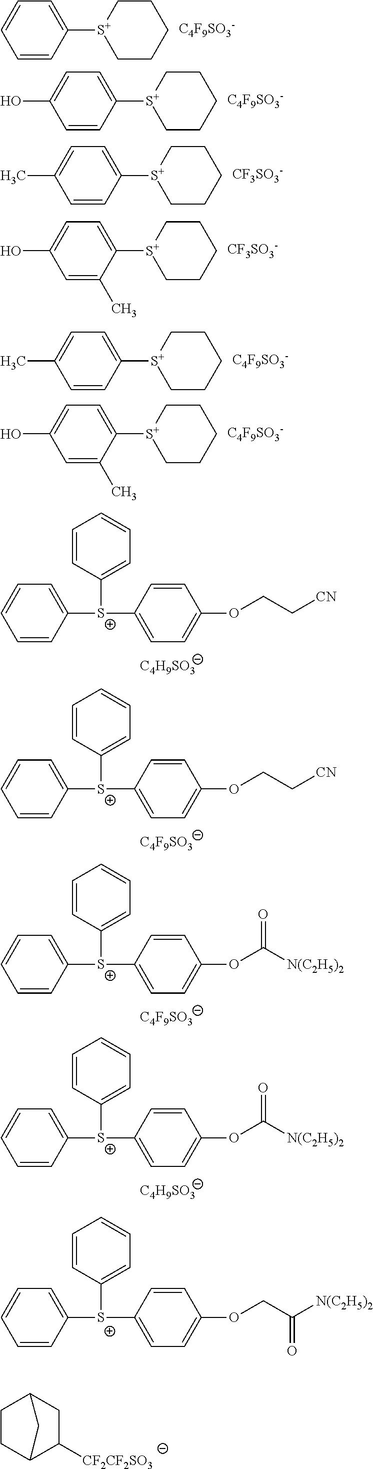

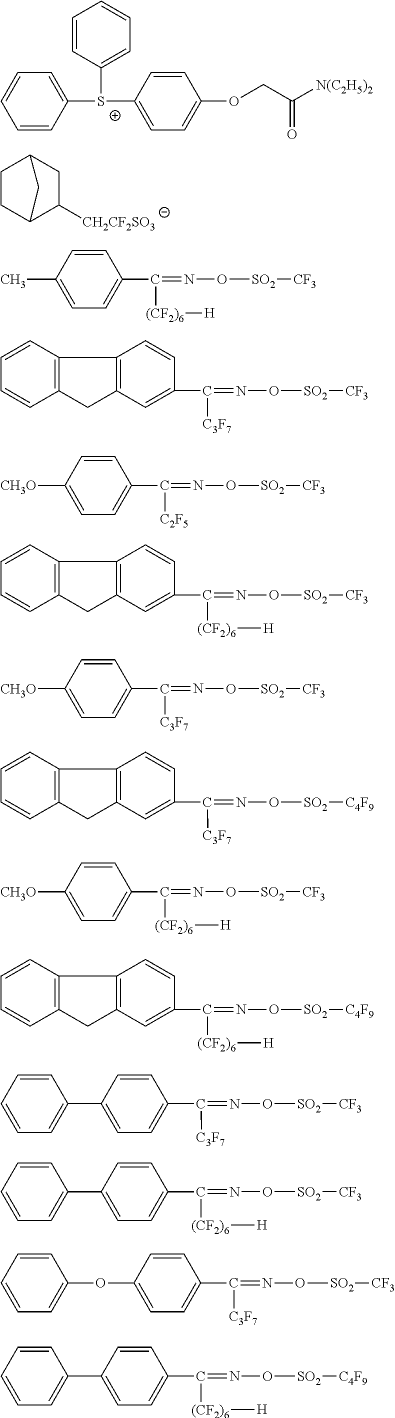

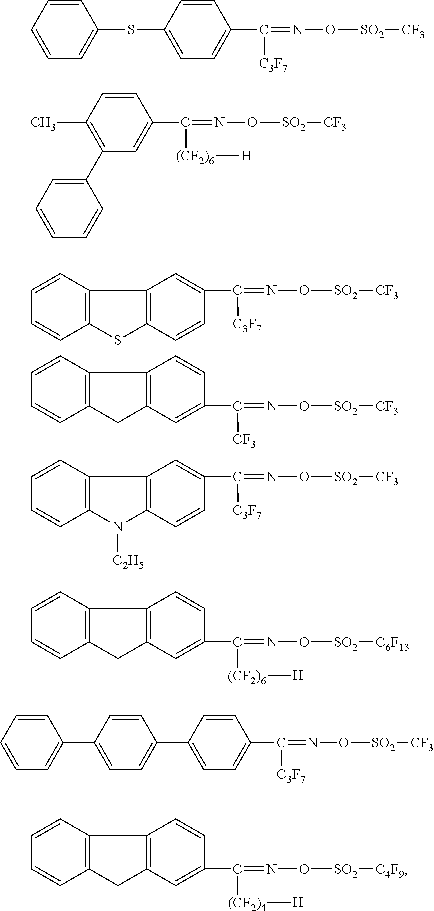

diphenyliodonium trifluoromethanesulfonate, diphenyliodonium nonafluorobutanesulfonate, bis(4-tert-butylphenyl)iodonium trifluoromethanesulfonate, bis(4-tert-butylphenyl)iodonium nonafluorobutanesulfonate, triphenylsulfonium trifluoromethanesulfonate, triphenylsulfonium heptafluoropropanesulfonate, triphenylsulfonium nonafluorobutanesulfonate, tris(4-methylphenyl)sulfonium trifluoromethanesulfonate, tris(4-methylphenyl)sulfonium heptafluoropropanesulfonate, tris(4-methylphenyl)sulfonium nonafluorobutanesulfonate, dimethyl(4-hydroxynaphthyl)sulfonium trifluoromethanesulfonate, dimethyl(4-hydroxynaphthyl)sulfoniumheptafluoropropanesulfonate, dimethyl(4-hydroxynaphthyl)sulfonium nonafluorobutanesulfonate, dimethylphenylsulfonium trifluoromethanesulfonate, dimethylphenylsulfonium heptafluoropropanesulfonate, dimethylphenylsulfonium nonafluorobutanesulfonate, diphenylmethylsulfonium trifluoromethanesulfonate, diphenylmethylsulfonium heptafluoropropanesulfonate, diphenylmethylsulfonium nonafluorobutanesulfonate, (4-methylphenyl)diphenylsulfonium trifluoromethanesulfonate, (4-methylphenyl)diphenylsulfonium heptafluoropropanesulfonate, (4-methylphenyl)diphenylsulfonium nonafluorobutanesulfonate, (4-methoxyphenyl)diphenylsulfonium trifluoromethanesulfonate, (4-methoxyphenyl)diphenylsulfonium heptafluoropropanesulfonate, (4-methoxyphenyl)diphenylsulfonium nonafluorobutanesulfonate, tris(4-tert-butylphenyl)sulfonium trifluoromethanesulfonate, tris(4-tert-butylphenyl)sulfonium heptafluoropropanesulfonate, tris(4-tert-butylphenyl)sulfonium nonafluorobutanesulfonate, diphenyl(1-(4-methoxy)naphthyl)sulfonium trifluoromethanesulfonate, diphenyl(1-(4-methoxy)naphthyl)sulfonium heptafluoropropanesulfonate, diphenyl(1-(4-methoxy)naphthyl)sulfonium nonafluorobutanesulfonate, di(1-naphthyl)phenylsulfonium trifluoromethanesulfonate, di(1-naphthyl)phenylsulfonium heptafluoropropanesulfonate, di(1-naphthyl)phenylsulfonium nonafluorobutanesulfonate, 1-(4-butoxynaphthyl)tetrahydrothiophenium perfluorooctanesulfonate, 1-(4-butoxynaphthyl)tetrahydrothiophenium 2-bicyclo[2.2.1.]hept-2-yl-1,1,2,2-tetrafluoroethanesulfonate, N-nonafluorobutanesulfonyloxybicyclo[2.2.1]hept-5-ene-2,3-dicarboxylimide, bis(isopropylsulfonyl)diazomethane, bis(p-toluenesulfonyl)diazomethane, bis(1,1-dimethylethylsulfonyl)diazomethane, bis(cyclohexylsulfonyl)diazomethane, bis(2,4-dimethylphenylsulfonyl)diazomethane, 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane and 1,10-bis(cyclohexylsulfonyldiazomethylsulfonyl)decane.

Onium salts having a fluorinated alkylsuofonate anion is preferable.

Component (b) contains one or more kinds of the acid generator.

The first photoresist composition usually contains 0.1 to 30% by weight of Component (b) and preferably contains 0.1 to 20% by weight of Component (b) based on the amount of solid components.

The first photoresist composition can contain a cross-linking agent. The cross-linking agent is not limited, and the cross-linking agent can be suitably selected from the cross-linking agents used in the art.

Examples of the cross-linking agent include urea-type cross-linking agents, alkylene urea-type cross-linking agents and glycoluril-type cross-linking agent, and glycoluril-type cross-linking agents are preferred.

Examples of the urea-type cross-linking agent include bis(methoxymethyl)urea, bis(ethoxymethyl)urea, bis(propoxymethyl)urea, and bis(butoxymethyl)urea. Among these, preferred is bis(methoxymethyl)urea.

Examples of the alkylene urea-type cross-linking agent include a compounds represented by the formula (XIX).

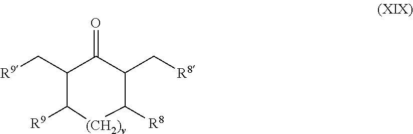

wherein R⁸ and R⁹ each independently represent a hydroxyl group or a C1-C4 alkoxy group, R^{8′} and R^{9′} each independently represent a hydrogen atom, a hydroxyl group or a C1-C4 alkoxy group, and v is an integer of 0 to 2.

R^{8′} and R^{9′} may be the same, or may be different, and R^{8′} and R^{9′} are preferably the same. R⁸ and R⁹ may be the same, or may be different, and R⁸ and R⁹ are preferably the same.

It is preferred that v is 0 or 1.

A compound represented by the formula (XIX) in which v is 0 or 1 is preferable.

The compound represented by the formula (XIX) can be obtained by a condensation reaction of alkylene urea and formalin followed by a reaction of the resulting product and a C1-C4 alcohol.

Specific examples of an alkylene urea-type cross-linking agent include ethylene urea-type cross-linking agents such as mono-hydroxymethylated ethylene urea, di-hydroxymethylated ethylene urea, mono-methoxymethylated ethylene urea, di-methoxymethylated ethylene urea, mono-ethoxymethylated ethylene urea, di-ethoxymethylated ethylene urea, mono-propoxymethylated ethylene urea, di-propoxymethylated ethylene urea, mono-butoxymethylated ethylene urea and di-butoxymethylated ethylene urea; propylene urea-type cross-linking agents such as mono-hydroxymethylated propylene urea, di-hydroxymethylated propylene urea, mono-methoxymethylated propylene urea, di-methoxymethylated propylene urea, mono-ethoxymethylated propylene urea, di-ethoxymethylated propylene urea, mono-propoxymethylated propylene urea, di-propoxymethylated propylene urea, and mono-butoxymethylated propylene urea and di-butoxymethylated propylene urea; 1,3-di(methoxymethyl)-4,5-dihydroxy-2-imidazolidinone and 1,3-di(methoxymethyl)-4,5-dimethoxy-2-imidazolidinone.

Examples of glycoluril-type cross-linking agents include a glycoluril compound in which the N-position is substituted with either or both a hydroxyalkyl group and/or a C1-C4 alkyl group having a C1-C4 alkoxy group. The glycoluril compound can be obtained by subjecting a glycoluril and formalin to a condensation reaction followed by reacting the product of this reaction with a C1-C4 alcohol.

Specific examples of glycoluril-type cross-linking agents include mono-, di-, tri- or tetra-hydroxymethylated glycoluril, mono-, di-, tri- and/or tetra-methoxymethylated glycoluril, mono-, di-, tri- and/or tetra-ethoxymethylated glycoluril, mono-, di-, tri- and/or tetra-propoxymethylated glycoluril, and mono-, di-, tri- and/or tetra-butoxymethylated glycoluril.

The cross-linking agent may be used singly or in a combination of two or more agents.

The content of the cross-linking agent is preferably 0.5 to 30 parts by weight per 100 parts by weight of the Component (A), and more preferably 0.5 to 10 parts by weight, and still more preferably 1 to 5 parts by weight. The formation of cross-linking is sufficiently promoted within this range and obtains a superior resist pattern. Furthermore storage stability of the resist coating liquid is superior and deterioration over time of its sensitivity can be suppressed.

In the first photoresist composition, performance deterioration caused by inactivation of acid which occurs due to post exposure delay can be diminished by adding an organic base compound, particularly a nitrogen-containing organic base compound as a quencher.

Specific examples of the nitrogen-containing organic base compound include nitrogen-containing organic base compounds represented by the following formulae:

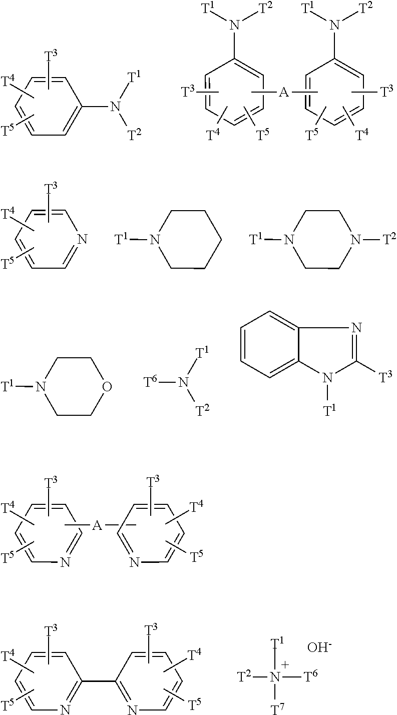

wherein T¹, T² and T⁷ each independently represent a hydrogen atom, a C1-C6 aliphatic hydrocarbon group, a C5-C10 alicyclic hydrocarbon group or a C6-C20 aromatic hydrocarbon group, and the aliphatic hydrocarbon group, the alicyclic hydrocarbon group and the aromatic hydrocarbon group may have one or more groups selected from the group consisting of a hydroxyl group, an amino group which may be substituted with a C1-C4 aliphatic hydrocarbon group and a C1-C6 alkoxy group,
T³, T⁴ and T⁵ each independently represent a hydrogen atom, a C1-C6 aliphatic hydrocarbon group, a C5-C10 alicyclic hydrocarbon group, a C6-C20 aromatic hydrocarbon group or a C1-C6 alkoxy group, and the aliphatic hydrocarbon group, the alicyclic hydrocarbon group, the aromatic hydrocarbon group and the alkoxy group may have one or more groups selected from the group consisting of a hydroxyl group, an amino group which may be substituted with a C1-C4 aliphatic hydrocarbon group and a C1-C6 alkoxy group,
T⁶ represents a C1-C6 aliphatic hydrocarbon group or a C5-C10 alicyclic hydrocarbon group, and the aliphatic hydrocarbon group and the alicyclic hydrocarbon group may have one or more groups selected from the group consisting of a hydroxyl group, an amino group which may be substituted with a C1-C4 aliphatic hydrocarbon group and a C1-C6 alkoxy group, and
A represents —CO—, —NH—, —S—, —S—S— or a C2-C6 alkylene group,

Examples of the amino group which may be substituted with the C1-C4 aliphatic hydrocarbon group include an amino group, a methylamino group, an ethylamino group, a butylamino group, a dimethylamino group and a diethylamino group. Examples of the C1-C6 alkoxy group include a methoxy group, an ethoxy group, a propoxy group, an isopropoxy group, a butoxy group, a tert-butoxy group, a pentyloxy group, a hexyloxy group and a 2-methoxyethoxy group.

Specific examples of the aliphatic hydrocarbon group which may have one or more groups selected from the group consisting of a hydroxyl group, an amino group which may be substituted with a C1-C4 aliphatic hydrocarbon group, and a C1-C6 alkoxy group include a methyl group, an ethyl group, a propyl group, an isopropyl group, a butyl group, a tert-butyl group, a pentyl group, a hexyl group, an octyl group, a nonyl group, a decyl group, a 2-(2-methoxyethoxy)ethyl group, a 2-hydroxyethyl group, a 2-hydroxypropyl group, a 2-aminoethyl group, a 4-aminobutyl group and a 6-aminohexyl group.

Specific examples of the alicyclic hydrocarbon group which may have one or more groups selected from the group consisting of a hydroxyl group, an amino group which may be substituted with a C1-C4 aliphatic hydrocarbon group and a C1-C6 alkoxy group include a cyclopentyl group, a cyclohexyl group, a cycloheptyl group and a cyclooctyl group.

Specific examples of the aromatic hydrocarbon group which may have one or more groups selected from the group consisting of a hydroxyl group, an amino group which may be substituted with a C1-C4 aliphatic hydrocarbon group and a C1-C6 alkoxy group include a phenyl group and naphthyl group.

Specific examples of the alkoxy group include a methoxy group, an ethoxy group, a propoxy group, an isopropoxy group, a butoxy group, a tert-butoxy group, a pentyloxy group and a hexyloxy group.

Specific examples of the alkylene group include an ethylene group, a trimethylene group, a tetramethylene group, a methylenedioxy group and an ethylene-1,2-dioxy group.

Specific examples of the nitrogen-containing organic base compounds include hexylamine, heptylamine, octylamine, nonylamine, decylamine, aniline, 2-methylaniline, 3-methylaniline, 4-methylaniline, 4-nitroaniline, 1-naphthylamine, 2-naphthylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 2,2′-dipicolylamine, 3,3′-dipicolylamine, tetramethylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).

A hindered amine compound having a piperidine skeleton as disclosed in JP 11-52575 A1 can be also used as the quencher.

In the point of forming patterns having higher resolution, the quaternary ammonium hydroxide is preferably used as the quencher.

When the basic compound is used as the quencher, the first photoresist composition preferably includes 0.01 to 2.5% by weight of the basic compound based on the total amount of the solid components.

The first photoresist composition can contain, if necessary, a small amount of various additives such as a sensitizer, a dissolution inhibitor, other polymers, a surfactant, a stabilizer and a dye as long as the effect of the present invention is not prevented.

The first photoresist composition is usually in the form of a photoresist liquid composition in which the above-mentioned ingredients are dissolved in a solvent. Solvents generally used in the art can be used. The solvent used is sufficient to dissolve the above-mentioned ingredients, have an adequate drying rate, and give a uniform and smooth coat after evaporation of the solvent.

Examples of the solvent include a glycol ether ester such as ethyl cellosolve acetate, methyl cellosolve acetate and propylene glycol monomethyl ether acetate; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

The second photoresist composition usually contains the above-mentioned one or more resins, the above-mentioned acid generators and one or more solvents. The second photoresist composition can contain the above-mentioned one or more quencher and the above-mentioned additives. The second photoresist composition can contain the above-mentioned cross-linking agent. The second photoresist composition may be the same as the first photoresist composition, and may be different from the first photoresist composition.

The process for producing a photoresist pattern of the present invention comprises the following steps (1) to (11):

(1) a step of applying the first photoresist composition on a substrate followed by conducting drying, thereby forming the first photoresist film,

(2) a step of prebaking the first photoresist film,

(3) a step of exposing the prebaked first photoresist film to radiation,

(4) a step of baking the exposed first photoresist film,

(5) a step of developing the baked first photoresist film with the first alkaline developer, thereby forming the first photoresist pattern,

(6) a step of forming a coating layer on the first photoresist pattern,

(7) a step of applying the second photoresist composition on the coating layer followed by conducting drying, thereby forming the second photoresist film,

(8) a step of prebaking the second photoresist film,

(9) a step of exposing the prebaked second photoresist film to radiation,

(10) a step of baking the exposed second photoresist film, and

(11) a step of developing the baked second photoresist film with the second alkaline developer, thereby forming the second photoresist pattern.

In the step (1), the first photoresist composition is applied onto a substrate by a conventional process such as spin coating. Examples of the substrate include a semiconductor substrate such as a silicon wafer, a plastic substrate, a metallic substrate, a ceramic substrate and these substrates on which a insulating film or a conducting film is applied. An anti-reflective coating film can be formed on the substrate. Examples of the anti-reflective coating composition for forming the anti-reflective coating film include commercially available anti-reflective coating compositions such as “ARC-29A-8” available from Brewer Co. The anti-reflective coating film is usually formed by applying onto the substrate by a conventional process such as spin coating followed by baking. The baking temperature is usually 190 to 250° C., preferably 195 to 235° C. and more preferably 200 to 220° C. The baking time is usually 5 to 60 seconds.

In the step (1), while the film thickness of the first photoresist composition is not limited, it is preferably tens of nanometers to hundreds of micrometers. After applying the first photoresist composition on the substrate, the formed first photoresist composition film is dried, thereby forming the first photoresist film. Examples of a drying process include natural drying, draught drying and drying under reduced pressure. The drying temperature is usually 10 to 120° C., and preferably 25 to 80° C., and the drying time is usually 10 to 3,600 seconds and preferably 30 to 1,800 seconds.

In the step (2), the first photoresist film formed in the step (1) is prebaked. The prebaking is usually conducted using a heating device. The prebaking temperature is usually 80 to 140° C., and the prebaking time is usually 10 to 600 seconds.

In the step (3), the first photoresist film prebaked in the step (2) is exposed to radiation. The exposure is usually conducted using a conventional exposure system such as KrF excimer laser exposure system (wave length: 248 nm), ArF excimer laser dry exposure system (wave length: 193 nm), ArF excimer laser liquid immersion exposure system (wave length: 193 nm), F₂ laser exposure system (wavelength: 157 nm) and a system radiating a harmonic laser belonging to far-ultraviolet region or vacuum ultraviolet region by converting a laser from a solid-state laser source by wavelength conversion.

In the step (4), the first photoresist film exposed in the step (3) is baked. The baking is usually conducted using a heating device. The baking temperature is usually 70 to 140° C., and the baking time is usually 30 to 600 seconds.

In the step (5), the first photoresist film baked in the step (4) is developed with the first alkaline developer, thereby forming the first photoresist pattern. As the first alkaline developer, any one of various alkaline aqueous solution used in the art is used. Generally, an aqueous solution of tetramethylammonium hydroxide or (2-hydroxyethyl)trimethylammonium hydroxide (commonly known as “choline”) is used.

In the step (6), the coating layer is formed on the first photoresist pattern. The step (6) preferably comprises the following steps (6a) to (6c):

(6a) a step of applying a coating composition comprising a resin for forming a coating layer and a solvent for a coating layer on the first photoresist pattern,

(6b) a step of baking the formed coating composition layer on the first photoresist pattern to prepare a coating film, and

(6c) a step of developing the baked coating film with the developer, thereby forming the coating layer on the first photoresist pattern.

In the step (6a), the coating composition is applied on the first photoresist pattern to form a coating composition layer, and the coating composition layer formed is usually dried. The applying method is not limited, and this applying is usually conducted by a conventional process such as spin coating and paddling.

In the step (6b), the formed coating composition layer on the first photoresist pattern is baked to prepare a coating film. By conducting this step, a resistance to an organic solvent, developer and/or radiation in the following step of the first photoresist pattern is improved and fidelity of the pattern profile of the first photoresist pattern in the following steps can be ensured. The baking temperature is usually 100 to 180° C., and the baking time is usually 10 to 300 seconds.

In the step (6c), the baked coating film is developed with the developer such as pure water and an alkaline developer, thereby forming the coating layer on the first photoresist pattern. Examples of the alkaline developer include the same as described above, and specific examples thereof include aqueous tetranethylammonium hydroxide solution and aqueous (2-hydroxyethyl)trimethylammonium hydroxide solution. The developer can contain a surfactant. After, developing, the first photoresist pattern coated with the coating layer can be baked. The baking temperature is usually 100 to 120° C., and the baking time is usually 10 to 300 seconds.

The coating composition used in the step (6) comprises a resin for forming a coating layer and a solvent for a coating layer.

The resin is preferably a resin comprising a structural unit represented by the formula (A1):

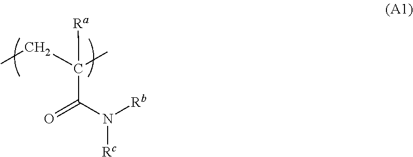

wherein R^{a} represents a hydrogen atom or a C1-C4 alkyl group, R^{b} and R^{c} each independently represent a hydrogen atom, a C1-C6 alkyl group or a C6-C10 aromatic hydrocarbon group, or R^{b} and R^{c} are bonded each other to form a C1-C6 alkylene group, and the alkyl group can have one or more hydroxyl group, the aromatic hydrocarbon group can have one or more C1-C4 perfluoroalkyl group, and one or more —CH₂— in the alkyl group and the alkylene group can be replaced by —O—, —CO— or —NR^{d}— in which R^{d} represents a hydrogen atom or a C1-C4 alkyl group, and —CH═CH— in the aromatic hydrocarbon group can be replaced by —CO—O—, and is more preferably a resin comprising a structural unit represented by the formula (A2):

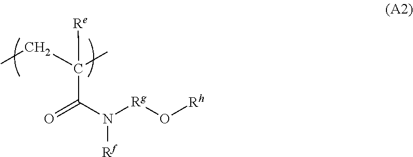

wherein R^{e}, R^{f} and R^{h} each independently represent a hydrogen atom or a C1-C4 alkyl group, R^{g} represents a C1-C4 alkylene group.

Examples of the C1-C4 alkyl group include a methyl group, an ethyl group, a propyl group, an isopropyl group, a butyl group and a tert-butyl group. Examples of the C1-C6 alkyl group include a methyl group, an ethyl group, a propyl group, an isopropyl group, a butyl group, a tert-butyl group, a pentyl group and a hexyl group. Examples of the C6-C10 aromatic hydrocarbon group include a phenyl group and a naphthyl group. Examples of the C1-C6 alkylene group include a methylene group, an ethylene group, a trimethylene group, a tetramethylene group, a pentamethylene group and a hexamethylene group. Examples of the C1-C4 perfluoroalkyl group include a trifluoromethyl group, a pentafluoroethyl group, a heptafluoropropyl group and a nonafluorobutyl group.

Examples of the monomer giving the structural unit represented by the formula (A1) include the followings.

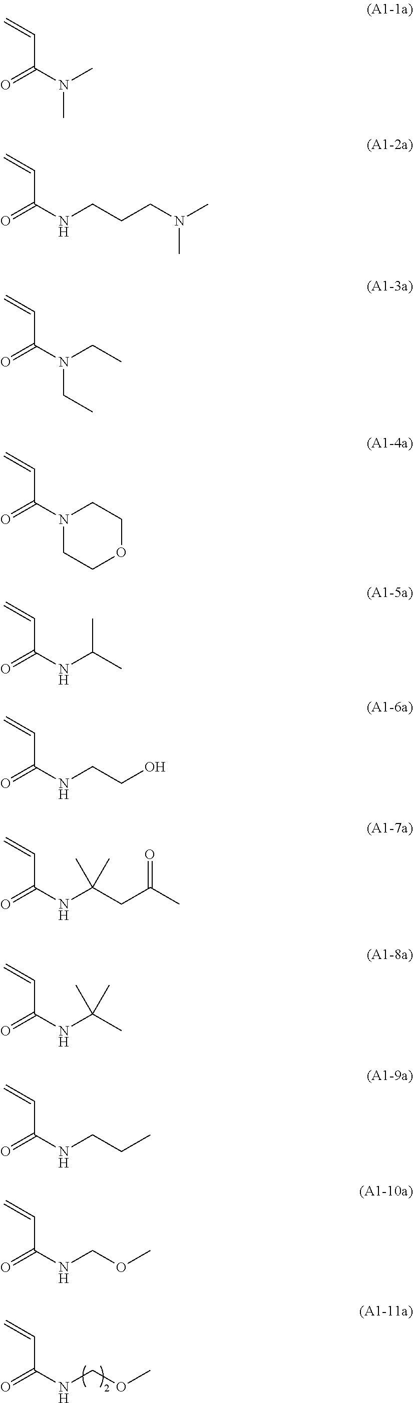

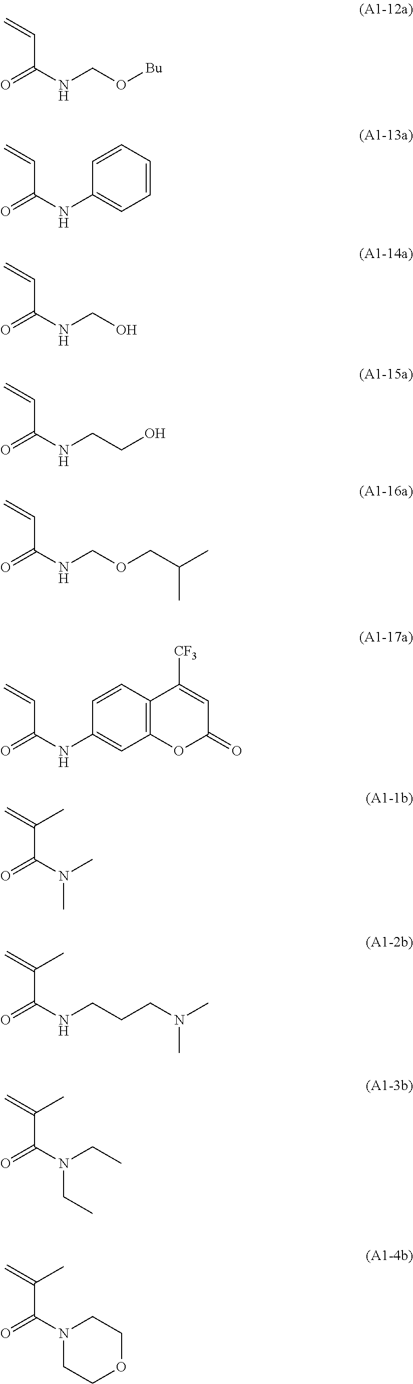

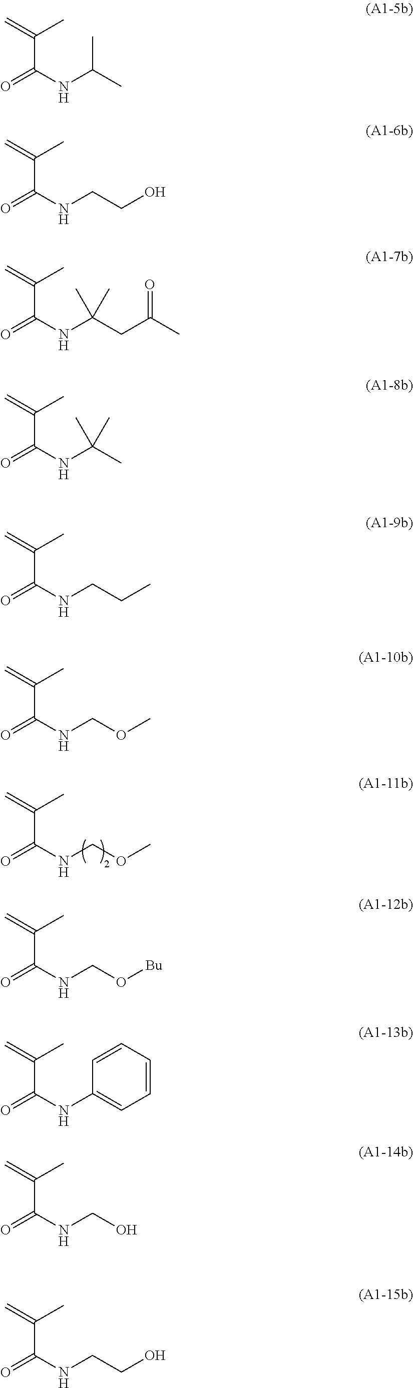

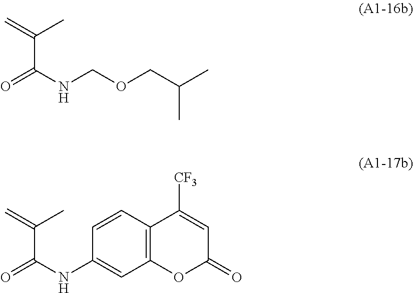

Among them, preferred are monomers represented by the formulae (A1-10a), (A1-15a), (A1-10b) and (A1-15b).

The resin for forming a coating layer may be homopolymer having one kind of the structural unit or copolymer having two or more kinds of the structural units.

The resin for forming a coating layer usually has 5,000 or more of the weight-average molecular weight, and preferably 7,000 or more of the weight-average molecular weight, and the resin for forming a coating layer preferably has 40,000 or less of the weight-average molecular weight, and more preferably 30,000 or less of the weight-average molecular weight. The weight-average molecular weight can be measured with gel permeation chromatography.

Examples of the solvent for a coating layer include water and a mixed solvent of water and an alcohol solvent. Examples of the alcohol solvent include methanol, ethanol, propanol, isopropanol, glycerin, ethylene glycol, propylene glycol, 1,2-butylene glycol, 1,3-butylene glycol and 2,3-butylene glycol. The amount of the alcohol solvent in the mixed solvent is preferably 30 parts by weight or less per 100 parts by weight of water.

The content of the resin for forming a coating layer is preferably 3 to 50% by weight based on the amount of the coating composition, and preferably 5 to 20% by weight.

In the step (7), the second photoresist composition is applied on the substrate on the coating layer formed in the step (6), followed by conducting drying, thereby forming the second photoresist film. This step is usually conducted according to the same manner as described in the step (1). The second photoresist composition usually contains one or more resins, one or more acid generators and one or more solvents. Examples of the resin include the same as described in Component (a) in the first photoresist composition. Examples of the acid generator include the same as described in Component (b) in the first photoresist composition. Examples of the solvent include the same as described above for the first photoresist composition. The second photoresist composition can contain one or more quenchers. The second photoresist composition can contain one or more above-mentioned additives. The second photoresist composition can contain the above-mentioned cross-linking agent. The second photoresist composition may be the same as the first photoresist composition, and may be different from the first photoresist composition.

In the step (8), the second photoresist film formed in the step (7) is prebaked, and this step is usually conducted according to the same manner as described in the step (2).

In the step (9), the prebaked second photoresist film is exposed to radiation, and this step is usually conducted according to the same manner as described in the step (3).

In the step (10), the exposed second photoresist film is baked, and this step is usually conducted according to the same manner as described in the step (4).

In the step (11), the baked second photoresist film is developed with the second alkaline developer, thereby forming the second photoresist pattern. As the second alkaline developer, the same as described as the first alkaline developer is usually used. This step is usually conducted according to the same manner as described in the step (5).

It should be construed that embodiments disclosed here are examples in all aspects and not restrictive. It is intended that the scope of the present invention is determined not by the above descriptions but by appended Claims, and includes all variations of the equivalent meanings and ranges to the Claims.

The present invention will be described more specifically by Examples, which are not construed to limit the scope of the present invention. The “%” and “part(s)” used to represent the content of any compound and the amount of any material to be used in the following Examples are on a weight basis unless otherwise specifically noted. The weight-average molecular weight (Mw) and the number-average molecular weight (Mn) of resins used in the following examples is a value found by gel permeation chromatography and the analysis condition is as followed.

### <Gel Permeation Chromatography Analysis Condition>

Apparatus: HLC-8120GPC Type, manufactured by TOSOH CORPORATION
Column: Three Columns of TSKgel Multipore HXL-M with a guard column, manufactured by TOSOH CORPORATION
Eluting Solvent: tetrahydrofuran
Flow rate: 1.0 mL/minute
Detector: RI detector

### Column Temperature: 40° C.

Injection amount: 100 μL

### Standard Reference Material: Standard Polystyrene

The molar ratio of the structural units in the resin was calculated based on the results of liquid chromatography.

In Resin Synthesis Examples, the following Monomer (A), Monomer (B), Monomer (C), Monomer (D), Monomer (E), Monomer (F), Monomer (G) and Monomer (H) were used.

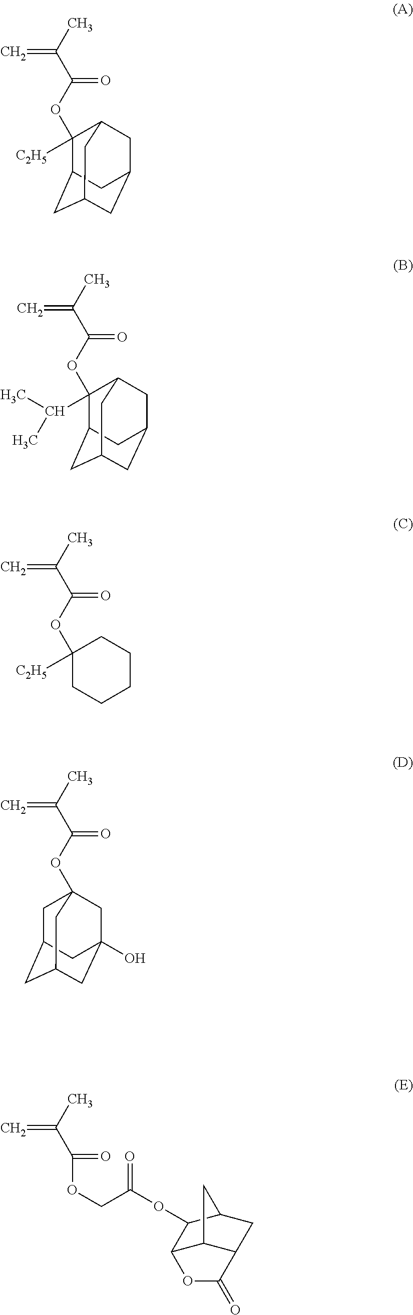

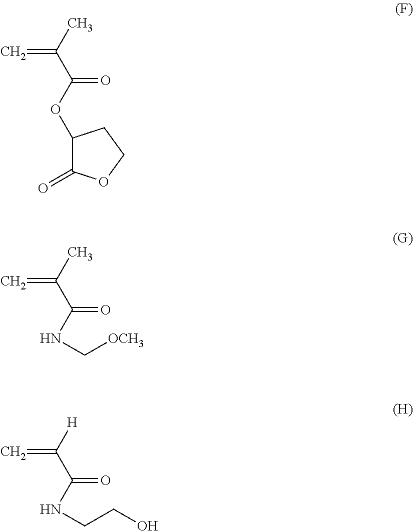

### Resin Synthesis Example 1

Into a four-necked flask equipped with a condenser and a thermometer, 27.78 parts of 1,4-dioxane was added, and then a nitrogen gas was blown into it for 30 minutes to substitute a gas in the flask to a nitrogen gas. After heating it up to 73° C. under nitrogen, a solution obtained by mixing 15.00 parts of Monomer (B), 5.61 parts of Monomer (C), 2.89 parts of Monomer (D), 12.02 parts of Monomer (E), 10.77 parts of Monomer (F), 0.34 part of 2,2′-azobisisobutyronitrile, 1.52 part of 2,2′-azobis(2,4-dimethylvaleronitrile) and 63.85 parts of 1,4-dioxane was added dropwise thereto over 2 hours at 73° C. The resultant mixture was heated at 73° C. for 5 hours. The reaction mixture was cooled down to room temperature and diluted with 50.92 parts of 1,4-dioxane. The resultant mixture was pored into a mixed solution of 481 parts of methanol and 120 parts of ion-exchanged water with stirring to cause precipitation. The precipitate was isolated and then, mixed with 301 parts of methanol followed by filtration to obtain the precipitate. This operation wherein the precipitate was mixed with 301 parts of methanol followed by filtration to obtain the precipitate was repeated three times. The obtained precipitate was dried under reduced pressure to obtain 37 parts of a resin having a Mw of 7.90×10³ and degree of dispersion (Mw/Mn) of 1.96. The yield thereof was 80%. This resin had the following structural units represented by the formulae (BB), (CC), (DD), (EE) and (FF), and the molar ratio of the structural units in the resin was 22.3/13.5/6.6/23.1/34.5 (structural unit (BB)/structural unit (CC)/structural unit (DD)/structural unit (EE)/structural unit (FF)). This is called as resin A1.

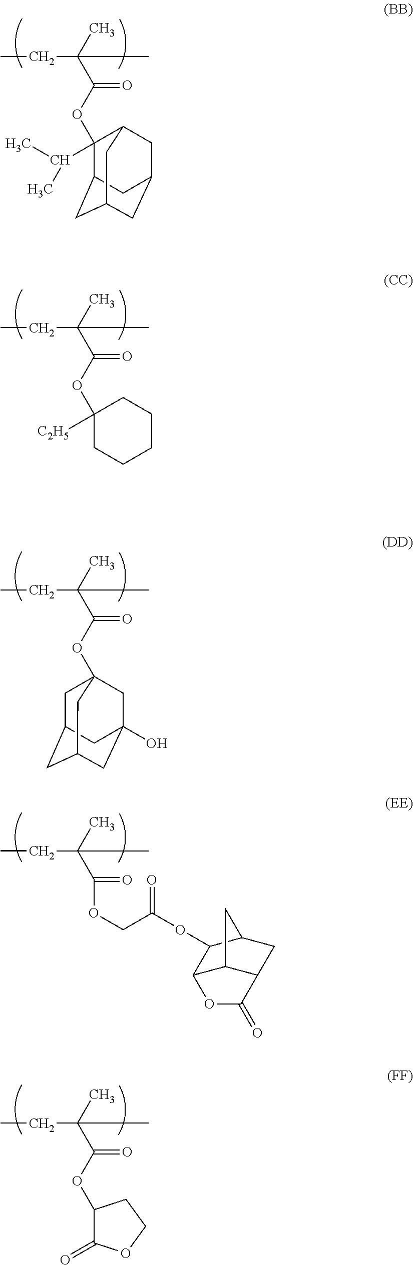

### Resin Synthesis Example 2

Into a four-necked flask equipped with a condenser and a thermometer, 23.66 parts of 1,4-dioxane was added, and then a nitrogen gas was blown into it for 30 minutes to substitute a gas in the flask to a nitrogen gas. After heating it up to 73° C. under nitrogen, a solution obtained by mixing 15.00 parts of Monomer (A), 2.59 parts of Monomer (C), 8.03 parts of Monomer (D), 13.81 parts of Monomer (F), 0.31 part of 2,2′-azobisisobutyronitrile, 1.41 part of 2,2′-azobis(2,4-dimethylvaleronitrile) and 35.49 parts of 1,4-dioxane was added dropwise thereto over 2 hours at 73° C. The resultant mixture was heated at 73° C. for 5 hours. The reaction mixture was cooled down to room temperature and diluted with 43.38 parts of 1,4-dioxane. The resultant mixture was pored into a mixed solution of 410 parts of methanol and 103 parts of ion-exchanged water with stirring to cause precipitation. The precipitate was isolated and then, mixed with 256 parts of methanol followed by filtration to obtain the precipitate. This operation wherein the precipitate was mixed with 256 parts of methanol followed by filtration to obtain the precipitate was repeated three times. The obtained precipitate was dried under reduced pressure to obtain 29.6 parts of a resin having a Mw of 8.5×10³ and degree of dispersion (Mw/Mn) of 1.79. The yield thereof was 75%. This resin had the following structural units represented by the formulae (AA), (CC), (DD) and (FF), and the molar ratio of the structural units in the resin was 27.7/6.6/19.3/46.5 (structural unit (AA)/structural unit (CC)/structural unit (DD)/structural unit (FF)). This is called as resin A2.

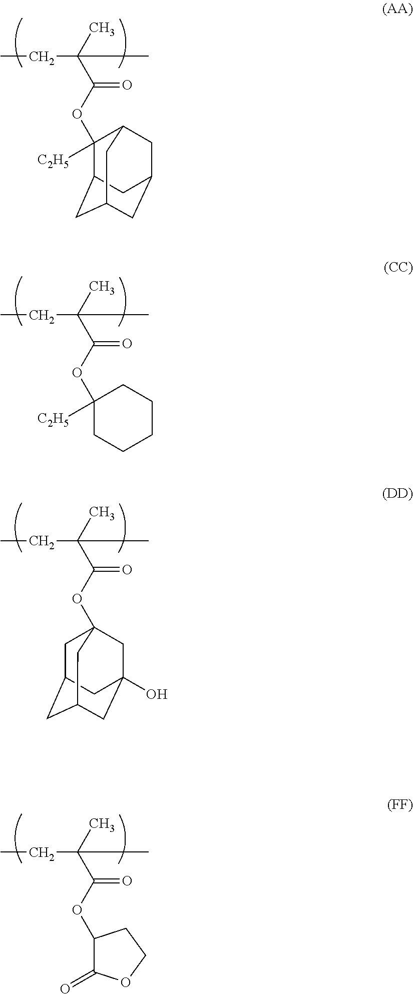

### Resin Synthesis Example 3

Into a four-necked flask equipped with a condenser and a thermometer, 27.5 parts of 1,4-dioxane was added, and then a nitrogen gas was blown into it for 30 minutes to substitute a gas in the flask to a nitrogen gas. After heating it up to 65° C. under nitrogen, a solution obtained by mixing 17.5 parts of Monomer (A), 3.0 parts of Monomer (C), 9.3 parts of Monomer (D), 16.1 parts of Monomer (F), 0.3 part of 2,2′-azobisisobutyronitrile, 1.3 part of 2,2′-azobis(2,4-dimethylvaleronitrile) and 37.7 parts of 1,4-dioxane was added dropwise thereto over 2 hours at 65° C. The resultant mixture was heated at 65° C. for 5 hours. The reaction mixture was cooled down to room temperature and diluted with 51 parts of 1,4-dioxane. The resultant mixture was pored into 596 parts of methanol with stirring to cause precipitation. The precipitate was isolated and washed three times with methanol. The obtained precipitate was dried under reduced pressure to obtain 32.7 parts of a resin having a Mw of 1.8×10⁴ and degree of dispersion (Mw/Mn) of 1.64. The yield thereof was 71%. This resin had the following structural units represented by the formulae (AA), (CC), (DD) and (FF), and the molar ratio of the structural units in the resin was 28.2/6.7/19.1/46.0 (structural unit (AA)/structural unit (CC)/structural unit (DD)/structural unit (FF)). This is called as resin A3.

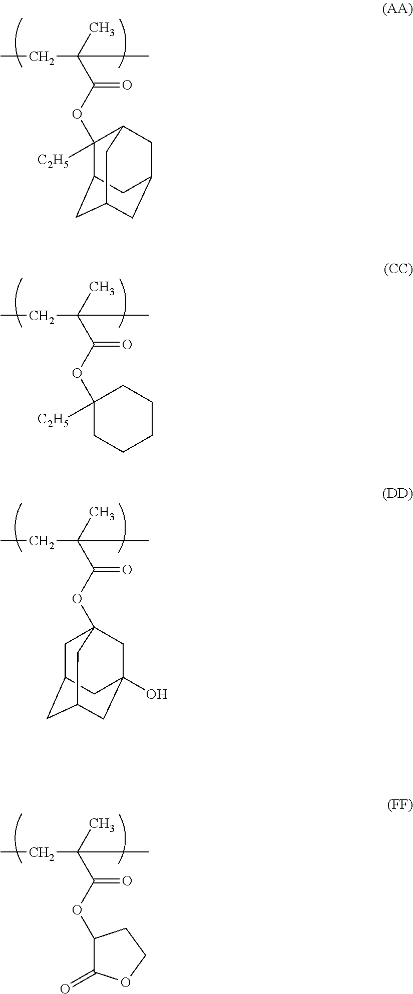

### Resin Synthesis Example 4

Into a four-necked flask equipped with a condenser and a thermometer, 44.2 parts of 2-propanol was added, and then a nitrogen gas was blown into it for 30 minutes to substitute a gas in the flask to a nitrogen gas. After heating it up to 77° C. under nitrogen, a solution obtained by mixing 2.3 parts of Monomer (G), 20.7 parts of Monomer (H), 0.33 part of 2,2′-azobisisobutyronitrile, 1.49 part of 2,2′-azobis(2,4-dimethylvaleronitrile) and 29.5 parts of 2-propanol was added dropwise thereto over 2 hours at 77° C. The resultant mixture was heated at 77° C. for 5 hours. The reaction mixture was cooled down to room temperature and pored into 299 parts of acetone with stirring to cause precipitation. The precipitate was isolated and washed three times with acetone. The obtained precipitate was dried under reduced pressure to obtain 19.1 parts of a resin in a yield of 83%. This resin had the following structural units represented by the formulae (GG) and (HH), and the molar ratio of the structural units in the resin was 91.1/8.9 (structural unit (GG)/structural unit (HH)). This is called as resin A4.

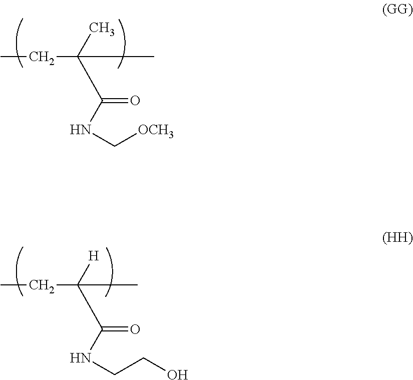

### Examples 1 to 3

### Resin

### A1: Resin A1

### A2: Resin A2

### A3: Resin A3

### A4: Resin A4

### <Acid Generator>

### B1:

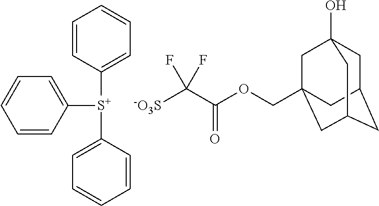

### <Cross-Linking Agent>

C1: compound represented by the following formula:

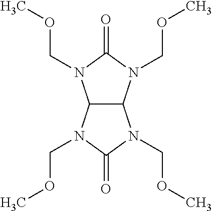

### <Basic Compound>

Q1: 2,6-diisopropylaniline
Q2: tri(methoxyethoxyethyl)amine

### <Solvent>

| | | | |
|---|---|---|---|
| S1: | propylene glycol monomethyl ether | 20 | parts |
| | 2-heptanone | 35 | parts |
| | propylene glycol monomethyl ether acetate | 290 | parts |
| | γ-butyrolactone | 3 | parts |
| S2: | pure water | 250 | parts |

The following components were mixed and dissolved, further, filtrated through a fluorine resin filter having pore diameter of 0.2 μm, to prepare photoresist compositions and a coating composition.

Resin (kind and amount are described in Table 1)

Acid generator (kind and amount are described in Table 1)

Cross-linking agent (kind and amount are described in Table 1)

Basic compound (kind and amount are described in Table 1)

Solvent (kind is described in Table 1)

TABLE 1

| | Resin | Acid | Cross- | Basic | |
|---|---|---|---|---|---|
| | (kind/ | generator | linking agent | compound | |
| | amount | (kind/amount | (kind/amount | (kind/amount | Sol- |
| | (part)) | (part)) | (part)) | (part)) | vent |
| Composition | A1/10 | B1/0.85 | C1/0.1 | Q2/0.16 | S1 |
| 1 | | | | | |
| Composition | A2/10 | B1/1.2 | — | Q1/0.13 | S1 |
| 2 | | | | | |
| Composition | A3/10 | B1/1.5 | — | Q1/0.12 | S1 |
| 3 | | | | | |
| Coating | A4/10 | — | — | | S2 |
| Composition | | | | | |
| 1 | | | | | |

In Example 1, Composition 1 was used as the first photoresist composition, and Composition 3 was used as the second photoresist composition. In Example 2, Composition 2 was used as the first photoresist composition. In Example 3, Composition 3 was used as the first photoresist composition, and Composition 3 was used as the second photoresist composition. In Examples 1 to 3, Coating Composition 1 was used as the coating composition.

Silicon wafers were each coated with “ARC-29A-8”, which is an organic anti-reflective coating composition available from Brewer Co., and then baked at 205° C. for 60 seconds on a hotplate, to form a 78 nm-thick organic anti-reflective coating. Each of the first photoresist compositions prepared as above was spin-coated over the anti-reflective coating so that the thickness of the resulting film became 95 nm after drying.

Each of the silicon wafers thus coated with the first photoresist composition was prebaked on a hotplate at a temperature shown in a column of “PB” in Table 2 for 60 seconds.

Using an ArF excimer stepper (“FPA-5000AS3” manufactured by CANON INC., NA=0.75, 2/3 Annular), each wafer thus formed with the respective photoresist film was subjected to line and space pattern exposure using a mask having line and space pattern (1:1.5) of which line width was 150 nm with an exposure dose shown in column of “Exposure Dose” in Table 2.

After the exposure, each wafer was subjected to a baking on a hotplate at a temperature shown in a column of “PEB” in Table 2 for 60 seconds.

After baking, each wafer was subjected to a paddle development for 60 seconds with an aqueous solution of 2.38 wt % tetramethylammonium hydroxide.

After the development, the obtained first pattern on the organic anti-reflective coating substrate was observed with a scanning electron microscope (“S-4100” manufactured by Hitachi, Ltd.), and line width thereof was measured. The results are shown in Table 2.

TABLE 2

| | PB | PEB | Exposure Dose | Line Width |
|---|---|---|---|---|
| Example No. | (° C.) | (° C.) | (mJ/cm²) | (nm) |
| 1 | 105 | 105 | 43 | 80.5 |
| 2 | 100 | 100 | 43 | 78.9 |
| 3 | 85 | 85 | 51 | 63.7 |

The first patterns were each coated with Coating Composition 1 by spin coating (spin rate: 1,500 rpm), and then baked at 150° C. for 60 seconds. Each of the first photoresist patterns coated with a coating composition film was washed with pure water using spin coater at a spin rate of 1,200 rpm for 10 seconds and then at a spin rate of 500 rpm for 15 seconds.

The obtained patterns were observed with the scanning electron microscope, and line width thereof was measured. The results are shown in Table 3.

TABLE 3

| Example No. | Line Width (nm) |
|---|---|
| 1 | 96.5 |
| 2 | 100.7 |
| 3 | 110.9 |

Further, the second photoresist composition prepared as above was spin-coated over the each of wafers on which the first photoresist pattern coated with a coating layer has been formed so that the thickness of the resulting film became 70 nm after drying.

The silicon wafers thus coated with the second photoresist composition were each prebaked on a hotplate at 85° C. for 60 seconds.

Using an ArF excimer stepper (“FPA-5000AS3” manufactured by CANON INC., NA=0.75, 2/3 Annular), each wafer thus formed with the respective photoresist film was subjected to line and space pattern exposure using a mask having line and space pattern (1:1.5) of which line width was 150 nm with an exposure dose shown in Table 4.

After the exposure, each wafer was subjected to a baking on a hotplate at 85° C. for 60 seconds.

After baking, each wafer was subjected to a paddle development for 60 seconds with an aqueous solution of 2.38 wt % tetramethylammonium hydroxide.

From the observation with the scanning electron microscope, the second line pattern was formed between the first line patterns and the pitch thereof became a half of that of the first photoresist pattern.

The shapes of the first and second photoresist patterns were good and the cross sectional shapes of the first and second photoresist patterns were also good, and the good photoresist pattern was obtained.

TABLE 4

| Example No. | Exposure Dose (mJ/cm²) |
|---|---|
| Ex. 1 | 27 |
| Ex. 3 | 35 |

According to the present invention, a good photoresist pattern is provided.

What is claimed is:

1. A process for producing a photoresist pattern comprising the following steps (1) to (11):
(1) a step of applying the first photoresist composition comprising a resin comprising a structural unit having an acid-labile group in its side chain and being itself insoluble or poorly soluble in an alkali aqueous solution but becoming soluble in an alkali aqueous solution by the action of an acid, and an acid generator, on a substrate followed by conducting drying, thereby forming the first photoresist film,
(2) a step of prebaking the first photoresist film,
(3) a step of exposing the prebaked first photoresist film to radiation,
(4) a step of baking the exposed first photoresist film,
(5) a step of developing the baked first photoresist film with the first alkaline developer, thereby forming the first photoresist pattern,
(6) a step of forming a coating layer on the first photoresist pattern,
(7) a step of applying the second photoresist composition on the coating layer followed by conducting drying, thereby forming the second photoresist film,
(8) a step of prebaking the second photoresist film,
(9) a step of exposing the prebaked second photoresist film to radiation,
(10) a step of baking the exposed second photoresist film, and
(11) a step of developing the baked second photoresist film with the second alkaline developer, thereby forming the second photoresist pattern.

2. The process according to claim 1, wherein the step (6) comprises the following steps (6a) to (6c):
(6a) a step of applying a coating composition comprising a resin for forming a coating layer and a solvent for a coating layer on the first photoresist pattern,
(6b) a step of baking the formed coating composition layer on the first photoresist pattern to prepare a coating film, and
(6c) a step of developing the baked coating film with the developer, thereby forming the coating layer on the first photoresist pattern.

3. The process according to claim 1 or 2, wherein the resin for forming a coating layer is a resin comprising a structural unit represented by the formula (A1): 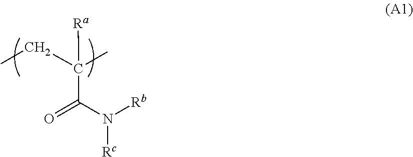
wherein R^{a} represents a hydrogen atom or a C1-C4 alkyl group, R^{b} and R^{c} each independently represent a hydrogen atom, a C1-C6 alkyl group or a C6-C10 aromatic hydrocarbon group, or R^{b} and R^{c} are bonded each other to form a C1-C6 alkylene group, and the alkyl group can have one or more hydroxyl group, the aromatic hydrocarbon group can have one or more C1-C4 perfluoroalkyl group, and one or more —CH₂— in the alkyl group and the alkylene group can be replaced by —O—, —CO— or —NR^{d}— in which R^{d} represents a hydrogen atom or a C1-C4 alkyl group, and —CH—CH— in the aromatic hydrocarbon group can be replaced by —CO—O—.

4. The process according to claim 1 or 2, wherein the resin for forming a coating layer is a resin comprising a structural unit represented by the formula (A2): 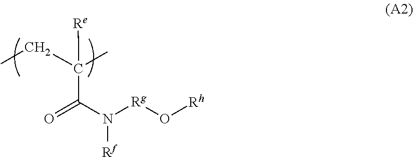
wherein R^{e}, R^{f} and R^{h} each independently represent a hydrogen atom or a C1-C4 alkyl group, R^{g} represents a C1-C4 alkylene group.

5. The process according to claim 1 or 2, wherein the solvent for a coating layer is water.
